(19) United States
(12) Patent Application Publication
(10) Pub. No.: US 2026/0262344 A1
(43) Pub. Date: Sep. 3, 2026

(54) DISPLAY PANEL AND METHOD FOR MANUFACTURING SAME, AND DISPLAY DEVICE

(71) Applicants: Hefei BOE Joint Technology Co., Ltd., Hefei, Anhui (CN); BOE Technology Group Co., Ltd., Beijing (CN); Beijing BOE Technology Development Co., Ltd., Beijing (CN)

(72) Inventors: Can YUAN, Beijing (CN); Yongqian LI, Beijing (CN)

(73) Assignees: Hefei BOE Joint Technology Co., Ltd., Hefei, Anhui (CN); BOE Technology Group Co., Ltd., Beijing (CN); Beijing BOE Technology Development Co., Ltd., Beijing (CN)

(21) Appl. No.: 18/837,204

(22) PCT Filed: Oct. 30, 2023
(86) PCT No.: PCT/CN2023/127855

§ 371 Date: Aug. 9, 2024

(51) Int. Cl. H10K 59/121; H10K 59/12; H10K 59/122; H10K 59/80

(52) U.S. Cl. CPC H10K 59/1216; H10K 59/1201; H10K 59/122; H10K 59/8792

(57) ABSTRACT

Provided is a display panel. The display panel includes: a display substrate and a cover plate that are opposite to each other, wherein the display substrate includes a substrate; and a plurality of repeat units on the substrate, wherein at least one of the plurality of repeat units is divided into a display region and a transparent region on at least one side of the display region, and includes a plurality of sub-pixels in the display region, wherein at least one of the plurality of sub-pixels includes a pixel circuit and a light-emitting element that are coupled.

### CROSS-REFERENCE TO RELATED APPLICATION

This application is a U.S. national stage of international application No. PCT/CN2023/127855, filed on Oct. 30, 2023, the disclosure of which is herein incorporated by reference in in its entirety.

### TECHNICAL FIELD

The present disclosure relates to the field of display technologies, and in particular, relates to a display panel and a method for manufacturing the same, and a display device.

### BACKGROUND

An organic light-emitting diode (OLED) is an active light-emitting element, and an OLED display panel equipped with the OLED has advantages, such as self-luminescence, low energy consumption, wide viewing angle, high contrast, and high brightness. Thus, the OLED display panel is widely used in the field of display technologies.

### SUMMARY

Embodiments of the present disclosure provide a display panel and a method for manufacturing the same, and a display device. The technical solutions are as follows.

In some embodiments of the present disclosure, a display panel is provided. The display panel includes: a display substrate and a cover plate that are opposite to each other, wherein the display substrate includes:
a substrate; and
a plurality of repeat units on the substrate, wherein at least one of the plurality of repeat units is divided into a display region and a transparent region on at least one side of the display region, and includes a plurality of sub-pixels in the display region, wherein at least one of the plurality of sub-pixels includes a pixel circuit and a light-emitting element that are coupled; wherein the pixel circuit is configured to drive the light-emitting element to emit light, and
the pixel circuit includes a storage capacitor, wherein the storage capacitor includes a first electrode plate and a second electrode plate of which orthographic projections on the substrate are overlapped; and the light-emitting element includes a first electrode; wherein the first electrode is connected to the first electrode plate via a transfer electrode;
the first electrode plate, the transfer electrode, the first electrode, and the second electrode plate are disposed in different layers; a material of the first electrode plate and a material of the first electrode both include a transparent conductive material; and at least one opening is defined in the display region, wherein the orthographic projection of the first electrode plate on the substrate and an orthographic projection of the first electrode on the substrate are both overlapped with an orthographic projection of the at least one opening on the substrate.

In some embodiments, a first opening and a second opening that are spaced apart are defined in the display region; and
the first electrode includes a first sub-electrode and a second sub-electrode that are spaced apart on a same layer, wherein the first sub-electrode is connected to the first electrode plate via the transfer electrode;
wherein an orthographic projection of the first sub-electrode on the substrate is overlapped with an orthographic projection of the first opening on the substrate, the orthographic projection of the first electrode plate on the substrate and an orthographic projection of the second sub-electrode on the substrate are both overlapped with an orthographic projection of the second opening on the substrate, and an orthographic projection of the transfer electrode on the substrate is within an orthographic projection of a space position between the first opening and the second opening on the substrate.

In some embodiments, the orthographic projection of the first sub-electrode on the substrate is not overlapped with the orthographic projections of the first electrode plate and the second electrode plate on the substrate, and the orthographic projection of the second sub-electrode on the substrate is overlapped with the orthographic projections of the first electrode plate and the second electrode plate on the substrate.

In some embodiments, the display substrate further includes: a pixel definition layer on a side, away from the substrate, of the first electrode,
wherein the pixel definition layer is configured to define the first opening and the second opening.

In some embodiments, the display panel further includes: a black matrix layer on a side, close to the display substrate, of the cover plate,
wherein an orthographic projection of the black matrix layer on the substrate is within an orthographic projection of the pixel definition layer on the substrate.

In some embodiments, the at least one opening includes a top-emission opening and a bottom-emission opening that are opposite to each other, wherein the top-emission opening is disposed in a side of the cover plate, and the bottom-emission opening is disposed in a side of the display substrate; and
the display substrate further includes a reflection electrode on a side, away from the substrate, of the first electrode,
wherein an orthographic projection of the reflection electrode on the substrate is overlapped with an orthographic projection of the bottom-emission opening on the substrate, and is not overlapped with an orthographic projection of the top-emission opening on the substrate.

In some embodiments, the reflection electrode is disposed between the first electrode and a pixel definition layer in the display substrate.

In some embodiments, the display substrate further includes: a first transparent conductive layer, an active layer, a gate metal layer, and a second transparent conductive layer that are sequentially laminated in a direction away from the substrate,
wherein the first electrode plate and the first transparent conductive layer are disposed on a same layer, the transfer electrode and the gate metal layer are disposed on a same layer, the first electrode and the second transparent conductive layer are disposed on a same layer, and the second electrode plate and the active layer are disposed on a same layer.

In some embodiments, the display substrate further includes: a light-emitting layer and a second electrode that are disposed between the first electrode and the cover plate and are sequentially laminated in the direction away from the substrate, wherein a material of the second electrode includes a transparent conductive material, and
a pixel definition layer in the display substrate is disposed between the light-emitting layer and the first electrode.

In some embodiments, a material of the first transparent conductive layer and a material of the second transparent conductive layer both include indium tin oxide, the material of the second electrode includes indium tin oxide, and a material of the active layer includes indium gallium zinc oxide.

In some embodiments, the display substrate further includes: a buffer layer and a gate insulative layer that are disposed between the first transparent conductive layer and the gate metal layer and are sequentially laminated in the direction away from the substrate,
and a passivation layer and a planarization layer that are disposed between the gate metal layer and the second transparent conductive layer and are sequentially laminated in the direction away from the substrate,
wherein the first electrode is connected to the transfer electrode through a first via running through the passivation layer and the planarization layer, and the transfer electrode is connected to the first electrode plate through a second via running through the gate insulative layer and the buffer layer.

In some embodiments, an orthographic projection of the first via on the substrate is not overlapped with an orthographic projection of the second via on the substrate, and
an area of the orthographic projection of the first via on the substrate is greater than an area of the orthographic projection of the second via on the substrate.

In some embodiments, an orthographic projection of the first via on the substrate and an orthographic projection of the second via on the substrate are both within an orthographic projection of a space position between the first opening and the second opening in the display region on the substrate.

In some embodiments, the display substrate further includes: a metal light shielding layer between the substrate and the buffer layer; and
the pixel circuit is further connected to a plurality of signal lines, and is configured to drive, in response to signals supplied over the plurality of signal lines, the light-emitting element to emit light,
wherein the plurality of signal lines include a first power line, a second power line, a scan line, a data line, and a sense line, wherein the scan line extends in a first direction and is disposed on a same layer as the gate metal layer, and the first power line, the second power line, the data line, and the sense line extend in a second direction and are disposed on a same layer as the metal light shielding layer, the first direction being intersected with the second direction.

In some embodiments, the gate metal layer is respectively connected to the metal light shielding layer, the first transparent conductive layer, and the active layer through a via running through the gate insulative layer.

In some embodiments, the display panel further includes a first color filter layer on a side, close to the display substrate, of the cover plate; and
the display substrate further includes a second color filter layer on a side, close to the substrate, of the first electrode;
wherein an orthographic projection of the first color filter layer on the substrate and an orthographic projection of the second color filter layer on the substrate are both overlapped with the orthographic projection of the at least one opening on the substrate.

In some embodiments, the second color filter layer is disposed between a passivation layer and a planarization layer in the display substrate.

In some embodiments of the present disclosure, a method for manufacturing a display panel is provided. The method is applicable to manufacturing the display panel in any above embodiment, and includes:
providing a substrate;
acquiring a display substrate by forming a plurality of repeat units on a side of the substrate; and
disposing a cover plate on an opposite side of the display substrate;
wherein at least one of the plurality of formed repeat units is divided into a display region and a transparent region on at least one side of the display region, and includes a plurality of sub-pixels in the display region, wherein at least one of the plurality of sub-pixels includes a pixel circuit and a light-emitting element that are coupled; wherein the pixel circuit is configured to drive the light-emitting element to emit light, and includes a storage capacitor, wherein the storage capacitor includes a first electrode plate and a second electrode plate of which orthographic projections on the substrate are overlapped. and the light-emitting element includes a first electrode; wherein the first electrode is connected to the first electrode plate via a transfer electrode;
the first electrode plate, the transfer electrode, the first electrode, and the second electrode plate are disposed in different layers, a material of the first electrode plate and a material of the first electrode both include a transparent conductive material; and at least one opening is defined in the display region, wherein the orthographic projection of the first electrode plate on the substrate and an orthographic projection of the first electrode on the substrate are both overlapped with an orthographic projection of the at least one opening on the substrate.

In some embodiments, the at least one opening includes a top-emission opening and a bottom-emission opening that are opposite to each other, wherein the top-emission opening is disposed in a side of the cover plate, and the bottom-emission opening is disposed in a side of the display substrate; and the method further includes:
forming a reflection electrode on a side, away from the substrate, of the first electrode,
wherein an orthographic projection of the formed reflection electrode on the substrate is overlapped with an orthographic projection of the bottom-emission opening on the substrate, and is not overlapped with an orthographic projection of the top-emission opening on the substrate.

In some embodiments of the present disclosure, a display device is provided. The display device includes: a power supply assembly, and the display panel in any above embodiment,
wherein the power supply assembly is connected to the display panel, and is configured to supply power to the display panel.

### BRIEF DESCRIPTION OF DRAWINGS

For clearer description of the technical solutions according to the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic section view of a display panel according to some embodiments of the present disclosure;

FIG. 2 is a schematic structural diagram of a display substrate according to some embodiments of the present disclosure;

FIG. 3 is a schematic structural diagram of a repeat unit in a display substrate according to some embodiments of the present disclosures;

FIG. 4 is a schematic structural diagram of a sub-pixel in a repeat unit in a display substrate according to some embodiments of the present disclosure;

FIG. 5 is a structural layout of a display substrate according to some embodiments of the present disclosure;

FIG. 6 is a locally structural layout of a display substrate according to some embodiments of the present disclosure;

FIG. 7 is a section view of a display substrate on the basis of FIG. 6;

FIG. 8 is a structural layout of an opening according to some embodiments of the present disclosure;

FIG. 9 is a structural layout of an opening and a reflection electrode according to some embodiments of the present disclosure;

FIG. 10 is a schematic section view of a display substrate according to some embodiments of the present disclosure;

FIG. 11 is a structural layout of a first transparent conductive layer in a display substrate according to some embodiments of the present disclosure;

FIG. 12 is a structural layout of a light shielding layer in a display substrate according to some embodiments of the present disclosure;

FIG. 13 is a structural layout of a first transparent conductive layer and a light shielding layer in a display substrate according to some embodiments of the present disclosure;

FIG. 14 is a structural layout of an active layer in a display substrate according to some embodiments of the present disclosure;

FIG. 15 is a structural layout of a first transparent conductive layer, a light shielding layer, and an active layer in a display substrate according to some embodiments of the present disclosure;

FIG. 16 is a structural layout of a gate insulative layer in a display substrate according to some embodiments of the present disclosure;

FIG. 17 is a structural layout of a first transparent conductive layer, a light shielding layer, an active layer, and a gate insulative layer in a display substrate according to some embodiments of the present disclosure;

FIG. 18 is a structural layout of a gate metal layer in a display substrate according to some embodiments of the present disclosure;

FIG. 19 is a structural layout of a first transparent conductive layer, a light shielding layer, an active layer, a gate insulative layer, and a gate metal layer in a display substrate according to some embodiments of the present disclosure;

FIG. 20 is a structural layout of a passivation layer in a display substrate according to some embodiments of the present disclosure;

FIG. 21 is a structural layout of a planarization layer in a display substrate according to some embodiments of the present disclosure;

FIG. 22 is a structural layout of a first transparent conductive layer, a light shielding layer, an active layer, a gate insulative layer, a gate metal layer, a passivation layer, and a planarization layer in a display substrate according to some embodiments of the present disclosure;

FIG. 23 is a structural layout of a second transparent conductive layer in a display substrate according to some embodiments of the present disclosure;

FIG. 24 is a structural layout of a first transparent conductive layer, a light shielding layer, an active layer, a gate insulative layer, a gate metal layer, a passivation layer, a planarization layer, and a second transparent conductive layer in a display substrate according to some embodiments of the present disclosure;

FIG. 25 is a structural layout of a pixel definition layer in a display substrate according to some embodiments of the present disclosure;

FIG. 26 is a structural layout of a first transparent conductive layer, a light shielding layer, an active layer, a gate insulative layer, a gate metal layer, a passivation layer, a planarization layer, a second transparent conductive layer, and a pixel definition layer in a display substrate according to some embodiments of the present disclosure;

FIG. 27 is a flowchart of a method for manufacturing a display panel according to some embodiments of the present disclosure;

FIG. 28 is an equivalent diagram of a method for manufacturing a display substrate on the basis of FIG. 7;

FIG. 29 is an equivalent diagram of a method for manufacturing a display substrate on the basis of FIG. 10; and

FIG. 30 is a schematic structural diagram of a display device according to some embodiments of the present disclosure.

### DETAILED DESCRIPTION

For clearer descriptions of the objects, technical solutions, and advantages of the embodiments of present disclosure, the embodiments of the present disclosure are described in detail hereinafter in combination with the accompanying drawings.

In some embodiments, the OLED display panel generally includes a substrate, and a plurality of pixels on the substrate. Each pixel includes a pixel circuit and an OLED light-emitting element. The pixel circuit is connected to the OLED light-emitting element to drive the OLED light-emitting element to emit light.

However, the current OLED display panel only emits light on a single side, and thus a display effect is poor.

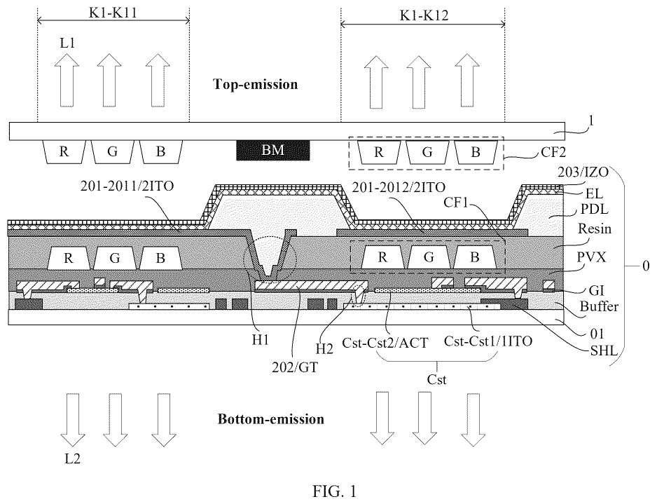

FIG. 1 is a schematic structural diagram of a display panel according to some embodiments of the present disclosure. As shown in FIG. 1, the display panel includes a display substrate 0 and a cover plate 1 that are opposite to each other.

On the basis of FIG. 1, FIG. 2 shows a schematic structural diagram of a display substrate. It can be seen referring to FIG. 2 that the display substrate 0 includes a substrate 01 and a plurality of repeat units 02 on the substrate 01.

In the plurality of repeat units 02, at least one repeat unit 02 is divided into a display region A1 and a transparent region A2 on at least one side of the display region A1, and includes a plurality of sub-pixels (not shown in FIG. 2) in the display region A1. At least one of the plurality of sub-pixels includes a pixel circuit and a light-emitting element that are coupled. The pixel circuit is configured to drive the light-emitting element to emit light, such that the pixel is lit up to emit rays.

Thus, it can be seen that the display region A1 in the repeat unit 02 is configured to display a screen in lighting up several pixels therein. The transparent region A2 is configured to transmit the rays, such that the repeat unit 02 displays images in the transparent state, that is, transparent display. In some embodiments, the repeat unit 02 is a basic unit for composing the display substrate, the display substrate 0 is formed by repeating the repeat units 02 in at least one direction. That is, the display substrate 0 is spliced by a plurality of repeat units 02.

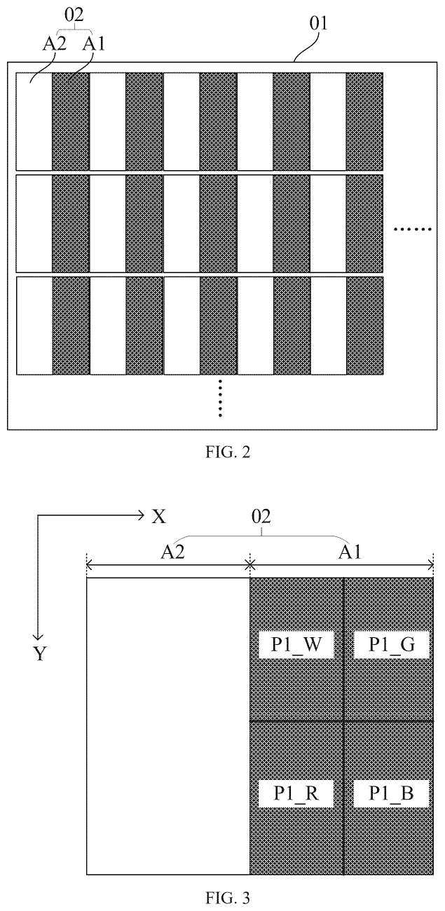

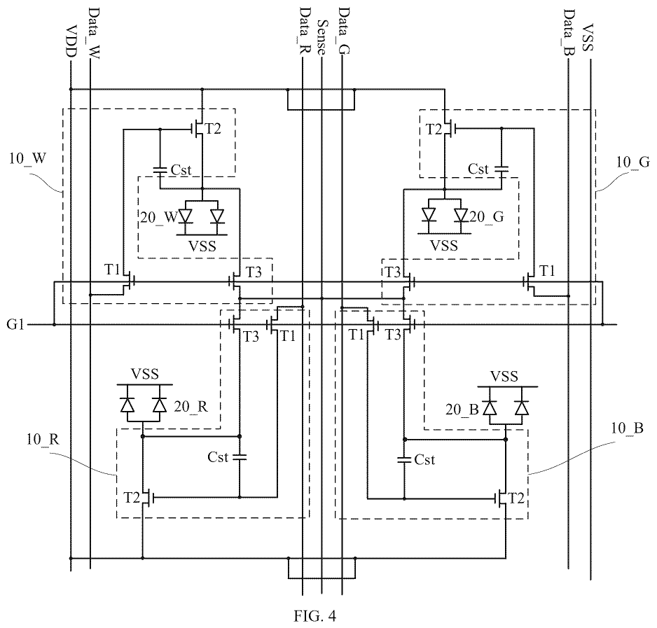

Illustratively, on the basis of FIG. 2, FIG. 3 shows a schematic structural diagram of a repeat unit. As shown in FIG. 3, the shown repeat unit 02 is divided into a display region A1 and a transparent region A2 on a side (for example, a left side) of the display region A1. The display region A1 is contiguous with, that is, adjacent to and in contact with the transparent region A2. The repeat unit 02 includes four sub-pixels P1 in the display region A1.

In some embodiments, referring to FIG. 3, the four sub-pixels P1 are a white (W) sub-pixel P1_W for emitting white light, a blue (B) sub-pixel P1_B for emitting blue light, a red (R) sub-pixel P1_R for emitting red light, and a green (G) sub-pixel P1_G for emitting green light.

In some embodiments, referring to FIG. 3, the white sub-pixel P1_W and the green sub-pixel P1_G are adjacent to each other and are arranged in a first direction X, the red sub-pixel P1 R and the blue sub-pixel P1_B are adjacent to each other and are arranged in the first direction X, the white sub-pixel P1_W and the red sub-pixel P1_R are adjacent to each other and are arranged in a second direction Y, and the green sub-pixel P1_G and the blue sub-pixel P1_B are adjacent to each other and are arranged in the second direction Y. That is, the four sub-pixels are arranged in a square, such that an aperture ratio and an area of the transparent region are efficiently improved, and the display effect is great.

The first direction X and the second direction Y are intersected, for example, the first direction X is perpendicular to the second direction Y. On the premise that a plurality rows and a plurality of columns pixels (multiple pixel rows and multiple pixel columns) are defined, the first direction X refers to a row direction, and the second direction Y refers to a column direction.

It should be noted that the above embodiments are only illustrative examples of a region division mode, a number of sub-pixels, arrangement of the sub-pixels, and colors of the sub-pixels, which are not limited in the embodiments of the present disclosure.

As described above, the sub-pixel includes the pixel circuit and the light-emitting element that are coupled, and the pixel circuit is configured to drive the light-emitting element to emit light. On this basis, In conjunction with FIG. 3, FIG. 4 illustratively shows a structure of a circuit of a pixel. It can be seen from FIG. 4 that the pixel circuit 10 in the sub-pixel is of 3T1C structure, that is, includes a first transistor T1, a second transistor T2, a third transistor T3, and a storage capacitor Cst. The structure is illustratively described. For example, in some embodiments, the pixel circuit 10 is of 7T1C or 6T2C structure, and the like.

A gate of the first transistor T1 is coupled to a scan line G1, a first electrode of the first transistor T1 is coupled to a data line Data, and a second electrode of the first transistor T1 is coupled to a gate of the second transistor T2. In the case that an on signal (that is, a scan signal at a valid potential) is supplied on the scan line G1, the first transistor T1 is turned on, such that a data signal supplied over the data line Data is transmitted to the gate of the second transistor T2. In the case that an off signal (that is, a scan signal at an invalid potential) is supplied on the scan line G1, the first transistor T1 is turned off. Correspondingly, the first transistor T1 is also referred to as a data write transistor.

A first electrode of the second transistor T2 is coupled to a first power line VDD, and a second electrode of the second transistor T2 is coupled to a first electrode of the light-emitting element 20. The second transistor T2 transmits a light-emitting drive signal to the first electrode of the light-emitting element 20 based on the data signal received by the gate of the second transistor T2 and a first power signal supplied over the first power line VDD. For example, in the case that the light-emitting element 20 is the OLED, the light-emitting drive signal is a drive current. The second electrode of the light-emitting element 20 is coupled to a second power line VSS. The light-emitting element 20 emits light under a potential difference between the light-emitting drive signal and a second power signal supplied over the second power line VSS. Correspondingly, the second transistor T2 is also referred to as a drive transistor.

A gate of the third transistor T3 is coupled to the scan line G1, a first electrode of the third transistor T3 is coupled to the second electrode of the second transistor T2 (that is, the first electrode of the light-emitting element 20), and a second electrode of the third transistor T3 is coupled to a sense line. In the case that an on signal (that is, a scan signal at a valid potential) is supplied on the scan line G1, the third transistor T3 is turned on, and is externally compensated in response to a threshold voltage Vth of the second transistor T2 extracted by compensation timing and a mobility. In the case that an off signal (that is, a scan signal at an invalid potential) is supplied on the scan line G1, the third transistor T3 is turned off. Correspondingly, the third transistor T3 is also referred to as a compensation transistor.

A first end of the storage capacitor Cst is coupled to the second electrode of the second transistor T2, and a second end of the storage capacitor Cst is coupled to the gate of the second transistor T2. The storage capacitor Cst is configured to store a potential of the gate of the second transistor T2.

It should be noted that for distinguishing, in FIG. 4, the pixel circuit in the white sub-pixel P1_W is marked as 10_W, and the light-emitting element 20 in the white sub-pixel P1_W is marked as 20_W; the pixel circuit in the green sub-pixel P1_G is marked as 10_G, and the light-emitting element 20 in the green sub-pixel P1_G is marked as 20_G; the pixel circuit in the red sub-pixel P1_R is marked as 10_R, and the light-emitting element 20 in the red sub-pixel P1_R is marked as 20_R; and the pixel circuit in the blue sub-pixel P1_B is marked as 10_B, and the light-emitting element 20 in the blue sub-pixel P1_B is marked as 20_B.

In some embodiments, the transistors in the pixel circuit 10 in the embodiments of the present disclosure all are N-type transistors, and correspondingly, the valid potential in the above embodiments is a high potential relative to the invalid potential. In some embodiments, the transistors in the pixel circuit 10 all are P-type transistors, and correspondingly, the valid potential in the above embodiments is a low potential relative to the invalid potential. In some embodiments, the pixel circuit 10 includes N-type transistors and P-type transistors. In the case that the pixel circuit 10 includes transistors of the same type, the technological process is simplified, the process difficulty is reduced, and the yield of the product is improved. For the first and second electrodes of the transistor, one electrode is the source, and the other electrode is the drain. For example, in the some embodiments of the present disclosure, the first electrode is the source, and the second electrode is the drain.

In some embodiments of the present disclosure, the N-type transistor is an oxide thin film transistor using an oxide material, and the P-type transistor is a low-temperature poly-silicon (LTPS) thin film transistor using a LTPS material. The material of the transistor herein refers to a material of the active layer in the transistor. The LTPS thin film transistor has advantages of high mobility and fast charging, and the oxide thin film transistor has advantages of low leakage current. Thus, on the basis of disposing both the P-type transistor and the N-type transistor in the pixel circuit 10, the LTPS thin film transistor and the oxide thin film transistor are integrated in a display substrate. That is, the display substrate is an LTPS+Oxide (LTPO for short) display substrate. Furthermore, the advantages of the LTPS thin film transistor and the oxide thin film transistor are utilized to achieve low-frequency drive, reduce power consumption, and thus improve display quality.

In some embodiments of the present disclosure, a potential of the first power signal supplied over the first power line VDD is constantly a high potential, and a potential of the second power signal supplied over the second power line VSS is constantly a low potential. The high potential and the low potential are relative to each other.

In some embodiments, as described in the above embodiments, the light-emitting element 20 is the OLED. Correspondingly, the first electrode is the anode, and the second electrode is the cathode. In some embodiments, the first electrode is the cathode, and the second electrode is the anode. A light-emitting layer is disposed between the first electrode and the second electrode, and emits light under a potential difference between the first electrode and the second electrode. In some embodiments, the light-emitting element 20 is of other types, for example, a quantum dot light-emitting diode (QLED), which is not limited in the embodiments of the present disclosure.

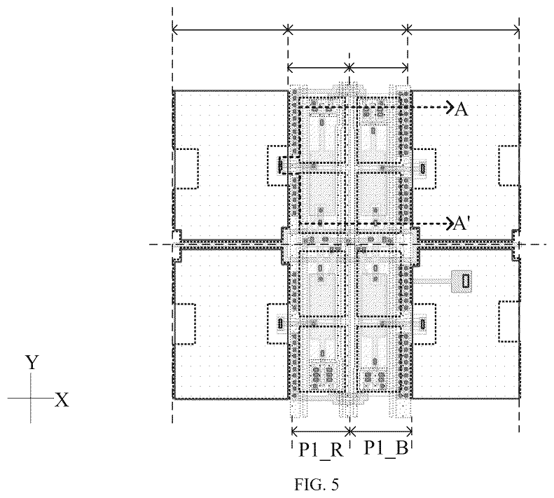

On the basis of FIG. 4, FIG. 5 is a structural layout of a display substrate. The structure shown in FIG. 1 is a section of the structural layout shown in FIG. 5 in an AA′ direction.

It can be seen referring to FIG. 1 that the pixel circuit includes the storage capacitor Cst. The storage capacitor Cst includes a first electrode plate Cst1 and a second electrode plate Cst2 of which orthographic projections on the substrate are overlapped.

The first electrode plate Cst1 refers to a first end of the storage capacitor Cst coupled to the second electrode (that is, a first electrode of the light-emitting element 20, for example, the anode) of the second transistor T2, and the first electrode plate Cst1 and the anode of the light-emitting element 20 are signal-synchronous. The second electrode plate Cst2 refers to a second end of the storage capacitor Cst coupled to the gate of the second transistor T2, and the second electrode plate Cst2 and the second transistor T2 are signal-synchronous.

The light-emitting element 20 includes a first electrode 201 (that is, the first electrode, also referred to as the anode). The first electrode 201 is connected to the first electrode plate Cst1 via a connection electrode 202, such that the first end of the storage capacitor Cst is coupled to the anode (that is, the second electrode of the second transistor T2) of the light-emitting element 20.

In addition, the first electrode plate Cst1, the connection electrode 202, the first electrode 201, and the second electrode plate Cst2 are disposed in different layers, and a material of the first electrode plate Cst1 and a material of the first electrode Cst2 both include a transparent conductive material, such that the storage capacitor Cst is considered as a transparent capacitor.

At least one opening K1 is defined in the display region A1, and the orthographic projection of the first electrode plate Cst1 on the substrate 01 and an orthographic projection of the first electrode K1 on the substrate 01 are both overlapped with an orthographic projection of the at least one opening K1 on the substrate 01. As the orthographic projection of the second electrode plate Cst2 on the substrate 01 is overlapped with the orthographic projection of the first electrode plate Cst1 on the substrate 01, an orthographic projection of the storage capacitor Cst on the substrate 01 is overlapped with the orthographic projection of the at least one opening K1 on the substrate 01. For example, a first opening K11 and a second opening K12 that are spaced apart are defined in the display region A1 in the drawing, and a space position between the two openings is a non-transparent region, that is, the space position is not transparent.

As such, in the display panel in the embodiments of the present disclosure, the storage capacitor Cst is formed by a transparent capacitor, and thus has a double-sided light emission effect when overlapped with the opening. Specifically, a region of the storage capacitor Cst is regarded as a joint portion of the top-emission opening and the bottom-emission opening to achieve emission of the top and bottom faces, such that the opening is optimized to optimize the display of the product.

In conjunction with FIG. 1, the top-emission means that emission of rays (marked as L1) from a side of the cover plate 1 in a direction away from the display substrate 0, and the bottom-emission means that emission of rays (marked as L2) from a side of the substrate 0 in a direction away from the cover plate 1.

In summary, the embodiments of the present disclosure provide a display panel. The display panel includes a substrate, and a plurality of repeat units on the substrate. The repeat unit is divided into a display region and a transparent region, and includes sub-pixels in the display region. The sub-pixel includes a pixel circuit and a light-emitting element that are coupled. The pixel circuit is configured to drive the light-emitting element to emit light, and includes a storage capacitor. In the display substrate, for a first electrode plate and a second electrode plate that are overlapped in the storage capacitor, the first electrode plate is connected to a first electrode of the light-emitting element via a transfer electrode. The first electrode plate and the first electrode are both made of a transparent conductive material, and are overlapped with an opening in the display region. As such, on the premise that the first electrode plate and the first electrode are reliably coupled at all portions thereof to ensure that the light-emitting element is reliably driven to emit light, double-sided light emission is achieved based on the transparent capacitor, and thus a display effect is great.

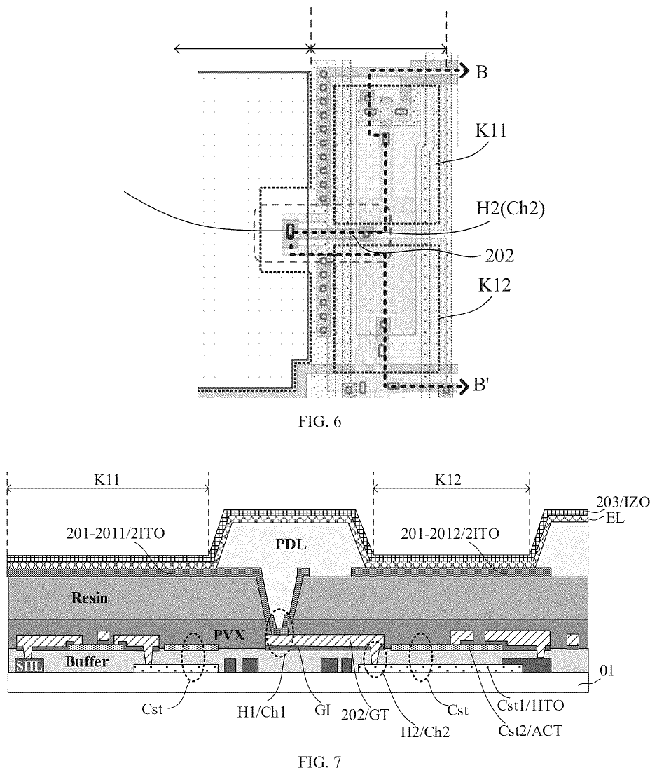

FIG. 6 is a locally structural layout of the structural layout shown in FIG. 5, and FIG. 7 is a section view of the structural layout shown in FIG. 5 in a BB′ direction. It can be seen referring to FIG. 1 and FIG. 7 that a first opening K11 and a second opening K12 that are spaced apart are defined in the display region A1.

The first electrode 201 includes a first sub-electrode 2011 and a second sub-electrode 2012 that are spaced apart on a same layer, and the first sub-electrode 2011 is connected to the first electrode plate Cst1 via the connection electrode 202.

An orthographic projection of the first sub-electrode 2011 on the substrate 01 is overlapped with an orthographic projection of the first opening K11 on the substrate 01, the orthographic projection of the first electrode plate Cst1 on the substrate 01 and an orthographic projection of the second sub-electrode 2012 on the substrate 01 are both overlapped with an orthographic projection of the second opening K12 on the substrate 01, and an orthographic projection of the connection electrode 202 on the substrate 01 is within an orthographic projection of a space position between the first opening K11 and the second opening K12 on the substrate 01, that is, within a non-transparent region. That is, the orthographic projection of the connection electrode 202 on the substrate is not overlapped with the orthographic projection of the first opening K11 on the substrate 01 and the orthographic projection of the second opening K12 on the substrate 01.

In some embodiments, it can be seen referring to FIG. 1 and FIG. 7 that the orthographic projection of the first sub-electrode 2011 on the substrate 01 is not overlapped with the orthographic projection of the first electrode plate Cst1 on the substrate 01 and the orthographic projection of the second electrode plate Cst2 on the substrate 01. That is, the orthographic projection of the first sub-electrode 2011 on the substrate 01 is not overlapped with the orthographic projection of the storage capacitor Cst on the substrate 01. The orthographic projection of the second sub-electrode 2012 on the substrate 01 is overlapped with the orthographic projection of the first electrode plate Cst1 on the substrate 01 and the orthographic projection of the second electrode plate Cst2 on the substrate 01. That is, the orthographic projection of the second sub-electrode 2012 on the substrate 01 is overlapped with the orthographic projection of the storage capacitor Cst on the substrate 01. As shown in the drawing, the orthographic projection of the second sub-electrode 2012 on the substrate 01 is within the orthographic projection of the storage capacitor Cst on the substrate 01.

In some embodiments, it can be seen referring to FIG. 1 and FIG. 7 that the display substrate further includes a pixel definition layer PDL on a side, away from the substrate 01, of the first electrode 201. The pixel definition layer PDL is configured to define the first opening K11 and the second opening K12.

In some embodiments, a material of the pixel definition layer PDL includes polyimide, acrylic, polyethylene glycol terephthalate, or the like.

In some embodiments, it can be seen referring to FIG. 1 that the display panel further includes a black matrix layer BM on a side, close to the display substrate 0, of the cover plate 1.

An orthographic projection of the black matrix layer BM on the substrate 01 is within an orthographic projection of the pixel definition layer PDL on the substrate 01, such that it is determined that the space position between the first opening K11 and the second opening K12 is a non-transparent region that light cannot be transmitted.

That is, in conjunction with FIG. 6, in the embodiments of the present disclosure, the connection electrode 202 is disposed on a central position between the first opening K11 and the second opening K12, that is, the non-transparent region. A material of the connection electrode 202 is generally a metal material, that is, the connection electrode 202 is not transparent. As such, the connection electrode 202 is disposed in the non-transparent region to avoid an impact on a size of the opening, such that the opening is optimized to ensure the great display effect.

In some embodiments, it can be seen referring to FIG. 1 and FIG. 7 that the display substrate in the embodiments of the present disclosure further includes a first transparent conductive layer, an active layer, a gate metal layer GT, and a second transparent conductive layer that are sequentially laminated in a direction away from the substrate 01.

In some embodiments of the present disclosure, materials of the first transparent conductive layer and the second transparent conductive layer include indium tin oxide (ITO). Correspondingly, in the drawings, the first transparent conductive layer is marked as 1ITO, and the second transparent conductive layer is marked as 2ITO. A material of the active layer includes the oxide material or LTPS material as described above. For example, in the case that the active layer includes the oxide material, the material of the active layer is indium gallium zinc oxide (IGZO). Corresponding, in the drawings, the active layer is marked as IGZO. A material of the gate metal layer GT includes metal materials, such as aluminum (Al), argentum (Ag), and the like. Thus, it can be seen that the gate metal layer GT is a non-transparent layer, and is not transparent.

In some embodiments, it can be seen referring to FIG. 1 and FIG. 7 that in the embodiments of the present disclosure, the first electrode plate Cst1 and the first transparent conductive layer 1ITO are disposed on a same layer. The connection electrode 202 and the gate metal layer GT are disposed on a same layer, and the connection electrode 202 is not transparent as described above as the gate metal layer GT is not transparent. The first electrode 201 and the second transparent conductive layer 2ITO are disposed on a same layer, and the second electrode plate Cst2 and the active layer IGZO are disposed on a same layer.

It should be noted that being in the same layer refers to a layer structure formed by forming a film layer for a specific pattern using a same film-forming process and then patterning a film layer by a one pattern process using a same mask. Depending on different particular patterns, the one pattern process includes multiple exposures, development, or etching processes, and the specific pattern in the formed layer structure is continuous or discontinuous. That is, multiple components, parts, structures, and/or parts in the “same layer” are made of the same material and formed by the same one pattern process. As such, the manufacturing process and manufacturing cost are saved, and the manufacturing efficiency is improved.

In some embodiments, it can be seen referring to FIG. 1 and FIG. 7 that the display substrate in the embodiments of the present disclosure further includes: a buffer layer Buffer and a gate insulative layer GI that are disposed between the first transparent conductive layer 1ITO and the gate metal layer GT and are sequentially laminated in the direction away from the substrate 01; and
a passivation layer PVX and a planarization layer that are disposed between the gate metal layer GT and the second transparent conductive layer 2ITO and are sequentially laminated in the direction away from the substrate 01.

In some embodiments, a material of the planarization layer includes a resin. Correspondingly, the planarization layer is marked as Resin.

The first electrode 201 is connected to the connection electrode 202 through a first via H1 running through the passivation layer PVX and the planarization layer Resin, and the connection electrode 202 is connected to the first electrode plate Cst1 through a second via H2 running through the gate insulative layer GI and the buffer layer Buffer.

That is, in the embodiments of the present disclosure, the storage capacitor Cst is a transparent capacitor formed by the first transparent conductive layer 1ITO and the active layer IGZO, and the anode of the light-emitting element 20 is a transparent capacitor formed by the second transparent conductive layer 2ITO. In conjunction with circuit shown in FIG. 4, the first transparent conductive layer 1ITO is an electrode of the second transistor T2 (that is, the drive transistor), is connected to the gate metal layer GT through the second via H2 running through the gate insulative layer GI and the buffer layer Buffer, and then is connected to the second transparent conductive layer 2ITO through the first via H1 running through the passivation layer PVX and the planarization layer Resin to form two channels Ch1 and Ch2 for entering the anode region of the light-emitting element 20.

One channel Ch1 of the two channels refers to a channel for connecting the connection electrode 202 to the first electrode (for example, the anode) of the light-emitting element 20, that is, a channel establishing connection through the first via H1. The other channel Ch2 of the two channels refers to a channel for connecting the first electrode plate Cst1 of the storage capacitor Cst to the connection electrode 202, that is, a channel establishing connection through the second via H2. As such, maintenance designs of sub-pixels are achieved through different channels.

In some embodiments, it can be seen referring to FIG. 1 and FIG. 7 that the light-emitting element 20 in the same layer as the gate metal layer GT includes two portions of an integrated structure. One portion is located in the second via H2, and is respectively connected to the first transparent conductive layer 1ITO and the other portion. The other portion is located on a side, away from the substrate 01, of the gate insulative layer GI, and is connected to the second transparent conductive layer 2ITO.

In some embodiments, it can be seen referring to FIG. 1 and FIG. 7 that the first electrode 201 in the same layer as the second transparent conductive layer 2ITO includes two portions of an integrated structure. One portion is located in the first via H1, and is respectively connected to the connection electrode 202 and the other portion. The other portion is located on a side, away from the substrate 01, of the planarization layer Resin. In addition, as shown in FIG. 1 and FIG. 7, in the portion in the first via H1, a structure of the via in the passivation layer PVX is in a “C” shape.

In some embodiments, it can be seen referring to FIG. 1 and FIG. 7 that an orthographic projection of the first via H1 on the substrate 01 is not overlapped with an orthographic projection of the second via H2 on the substrate 01, such that interference of signals transmitted by the two channel Ch1 and Ch2 is avoided.

In some embodiments, an area of the orthographic projection of the first via H1 on the substrate 01 is greater than an area of the orthographic projection of the second via H2 on the substrate 01, such that reliable connection of the connection electrode 202 to the first electrode 201 and the first electrode 201 with a greater area in the first electrode plate Cst1 is ensued, and reliable transmission of the signal is further ensured.

In some embodiments, the orthographic projection of the first via H1 on the substrate 01 and the orthographic projection of the second via H2 on the substrate 01 are both within the orthographic projection of the space position between the first opening K11 and the second opening K12 in the display region A1 on the substrate 01. That is, similar to the connection electrode, the first via H1 and the second via H2 are also defined in the non-transparent region to avoid light leakage through the via and an impact on the size of the opening, such that the opening is optimized to ensure the great display effect.

In some embodiments, it can be seen referring to FIG. 1 and FIG. 7 that the display substrate in the embodiments of the present disclosure further includes a metal light shielding layer SHL between the substrate 01 and the buffer layer Buffer.

In some embodiments of the present disclosure, the pixel circuit 10 is connected to a plurality of signal lines, and is configured to drive, in response to signals supplied over the plurality of signal lines, the light-emitting element 20 to emit light. As shown in FIG. 4, the plurality of signal lines include a first power line VDD, a second power line VSS, a scan line G1, a data line Data, and a sense line Sense.

The scan line G1 extends in a first direction X and is disposed on a same layer as the gate metal layer GT. The first power line VDD, the second power line VSS, the data line Data, and the sense line Sense extend in a second direction Y and are disposed on a same layer as the metal light shielding layer SHL.

In addition, the first direction X is intersected with the second direction Y. For example, Referring to FIG. 4, the first direction X is perpendicular to the second direction Y. On the premise that a plurality rows and a plurality of columns pixels are defined, the first direction X refers to a row direction, and the second direction Y refers to a column direction.

In some embodiments, in the pixel circuits 10 in the at least one sub-pixel, the gate of the first transistor T1 and the gate of the third transistor T3 are connected to a same scan line G1. In the pixel circuits 10 in the sub-pixels in at least one row direction, gates of a plurality of first transistors T1 and gates of a plurality of third transistors T3 are connected to a same scan line G1. In the pixel circuits 10 in the sub-pixels in at least one repeat unit 02, gates of a plurality of first transistors T1 and gates of a plurality of third transistors T3 are connected to a same scan line G1.

For example, referring to FIG. 4, in the pixel circuits 10 in the four sub-pixels in one repeat unit 02, gates of the four first transistors T1 and gates of the four third transistors T3 are connected to a same scan line G1. On this basis, it can be seen referring to FIG. 4 that the scan line G1 is of an annular design to facilitate the layout of the lines and save space.

In some embodiments, it can be seen referring to FIG. 4 that the first power line VDD and the second power line VSS are respectively disposed on two sides in the first direction X. The sense line Sense is disposed between the first power line VDD and the second power line VSS, and between two sub-pixels arranged in the first direction X. Two data lines between the sense line Sense and the first power line VDD and coupled to two sub-pixels arranged in the second direction Y are disposed between the sense line Sense and the first power line VDD. Similarly, Two data lines between the sense line Sense and the second power line VSS and coupled to two sub-pixels arranged in the second direction Y are disposed between the sense line Sense and the second power line VSS. In addition, positions of the first power line VDD and the first power line VDD are basically mirror symmetric with respect to the sense line Sense. Two data lines between the sense line Sense and the first power line VDD and two data lines between the sense line Sense and the second power line VSS are basically mirror symmetric with respect to the sense line Sense.

That is, in some embodiments, one scan line G1 defines two adjacent pixel rows, one sense line Sense defines two adjacent pixel columns, and the scan line G1 and the sense line Sense define four sub-pixels, that is, a repeat unit 02.

In some embodiments, it can be seen referring to FIG. 1 and FIG. 7 that the gate metal layer GT in the embodiments of the present disclosure is connected to the metal light shielding layer SHL, the first transparent conductive layer 1ITO, and the active layer IGZO through vias (not shown) running through the gate insulative layer GI to reliably establish connection of the circuit shown in FIG. 4.

In some embodiments, it can be seen referring to FIG. 1 and FIG. 7 that the display substrate in the embodiments of the present disclosure further includes a light-emitting layer and a second electrode 203 that are disposed between the first electrode 201 and the cover plate 1 and are sequentially laminated in the direction away from the substrate 01. The pixel definition layer PDL in the display substrate is disposed between the light-emitting layer EL and the first electrode 201.

In some embodiments, the light-emitting layer is electroluminescent. Correspondingly, in the drawings, the light-emitting layer is marked as EL. The second electrode 203 refers to the cathode of the light-emitting element 20. The light-emitting layer EL emits light under a potential difference signals received by the first electrode 201 and the second electrode 203. The signal received by the first electrode 201 is a light-emitting drive signal transmitted by the pixel circuit 10, and the signal received by the second electrode 2031 is a second power signal supplied over the second power line VSS.

In some embodiments, the light-emitting layer includes at least one of: a hole injection layer (HIL), a hole transport layer (HTL), an electron barrier layer (EBL), a hole barrier layer (HBL), an electron transport layer (ETL), or an electron injection layer (EIL). In manufacturing process, the light-emitting layer EL is formed by evaporating the mask plate, or formed by an inkjet process.

In some embodiments, a material of the second electrode 203 includes a transparent material to ensure the double-sided light emission. For example, the material of the second electrode 203 includes indium zinc oxide (IZO).

In some embodiments, it can be seen referring to FIG. 1 that the display panel in the embodiments of the present disclosure further includes a first color filter layer CF1 on a side, close to the display substrate 0, of the cover plate 1. An orthographic projection of the first color filter layer CF1 on the substrate 01 is overlapped with the orthographic projection of the opening K1 on the substrate 01. That is, the color filter layer is disposed on the side of the cover plate by a CF on cover glass process to achieve full-color display by the top-emission.

The display substrate further includes a second color filter layer CF2 on a side, close to the substrate 01, of the first electrode 201. An orthographic projection of the second color filter layer CF2 on the substrate 01 is overlapped with the orthographic projection of the opening K1 on the substrate 01. That is, the color filter layer is disposed on the side of the display substrate by a CF on array process to achieve full-color display by the bottom-emission.

For example, referring to FIG. 1, the second color filter layer CF2 is disposed between the passivation layer PVX and the planarization layer Resin in the display substrate to ensure the planarization of the color filter layer.

In some embodiments, it can be seen referring to FIG. 1 that both the first color filter layer CF1 and the second color filter layer CF2 include red (R), green (G) and blue (B) three primary color filter films. The description illustrates a color division, which is not limited in the embodiments of the present disclosure.

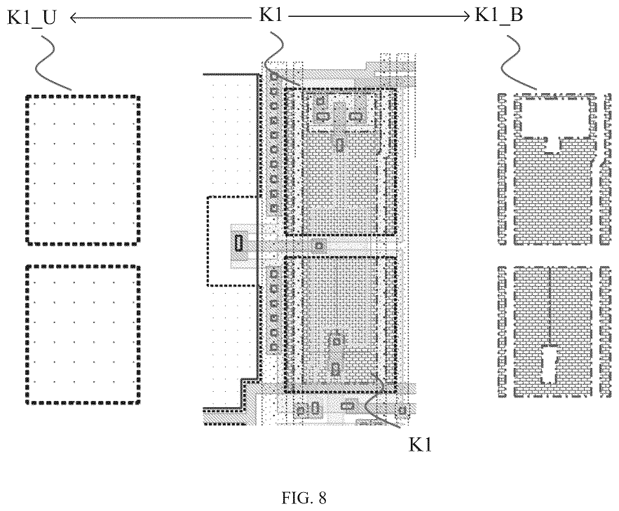

In some embodiments, it can be seen in conjunction with FIG. 1 and the locally structural layout in FIG. 8 that the opening K1 in the embodiments of the present disclosure includes a top-emission opening K1_U and a bottom-emission opening K1_B that are opposite to each other. The top-emission opening K1_U is disposed in a side of the cover plate 1 for top-emission display. The bottom-emission opening K1_B is disposed in a side of the display substrate for bottom-emission display. It can be seen in conjunction with FIG. 1 and FIG. 8 that for the top-emission opening K1_U for the top-emission display, a side of the bottom-emission opening K1_B for the bottom-emission display losses partial emission area due to shielding of the pixel circuit and the non-transparent electrode line (including the transistor and the light shielding layer SHL), which does not affect compatibility with the top and bottom double-sided display, such that the display is optimized.

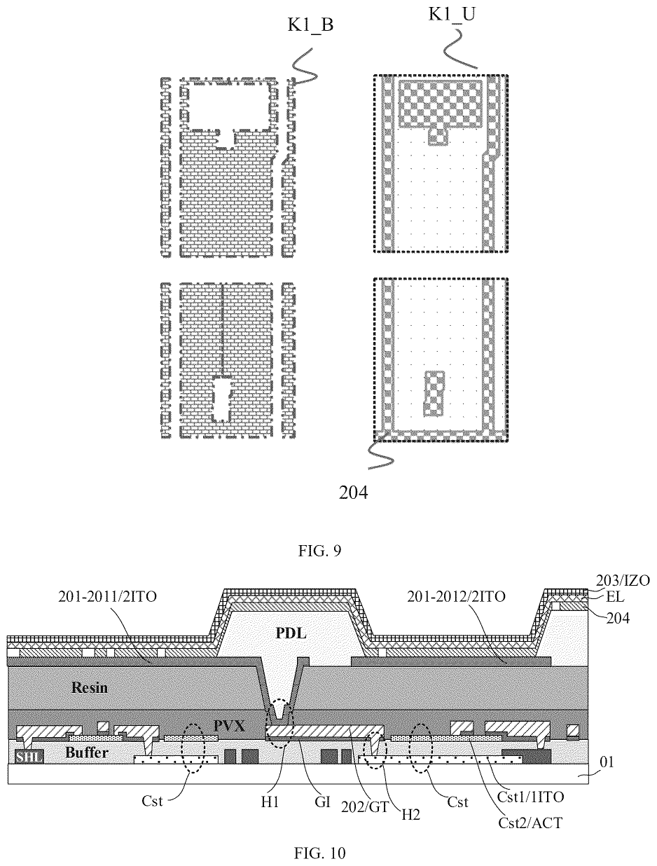

In some embodiments, it can be seen in conjunction with FIG. 8, the structural layout in FIG. 9 and the section view in FIG. 10 that the display substrate in the embodiments of the present disclosure further includes a reflection electrode 204 on a side, away from the substrate 01, of the first electrode 201.

For example, referring to FIG. 10, the reflection electrode 204 is disposed between the first electrode 201 and the pixel definition layer PDL in the display substrate 0.

An orthographic projection of the reflection electrode 204 on the substrate 01 is overlapped with an orthographic projection of the bottom-emission opening K1_B on the substrate 01, and is not overlapped with an orthographic projection of the top-emission opening K1_U on the substrate 01. That is, the reflection electrode 204 is a result of a logical NOT of the bottom-emission opening K1_B and the top-emission opening K1_U.

In some embodiments, a material of the reflection electrode 204 is a non-transparent metal material. By disposing the reflection electrode 204 at the above position, as the bottom-emission is not achieved due to shielding of the pixel circuit and the non-transparent electrode line, the luminescence yield of the top-emission is increased in the case that the bottom-emission is not affected. Specifically, the reflection electrode 204 performs microcavity enhancement on the top-emission region to increase the luminescence yield of the top-emission. Thus, compared with the scheme in FIG. 1, the power consumption of the product is reduced in the case that the luminance is fixed. The reflection electrode 204 is also referred to as a reflection anode.

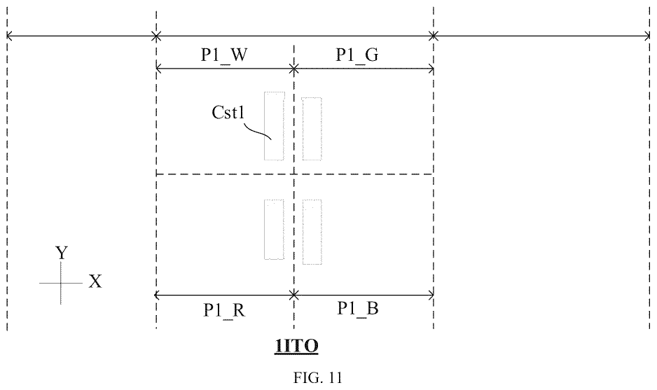

In some embodiments, by taking the repeat unit 01 in FIG. 4 as an example, in conjunction with FIG. 5, FIGS. 11 to 27 are structural layouts of different film layers. It can be seen referring to FIGS. 11 to 27 that a repeat unit 01 is divided into a display region A1 and a transparent region A2 on a side of the display region A1, and includes four sub-pixels in a “square” shape in the display region A1: a white sub-pixel P1_W, a green sub-pixel P1_G, a red sub-pixel P1_R, and a blue sub-pixel P1_B. It should be noted that the drawings only illustratively show structures of one sub-pixel, other repeated portions are similar, and thus are not marked.

(1) Referring to FIG. 11, a structural layout of a first transparent conductive layer 1ITO is illustrated. It can be seen referring to FIG. 11 that the first transparent conductive layer 1ITO is configured to form the first electrode plate Cst1 (that is, the first end of the storage capacitor Cst) of the storage capacitor Cst. That is, as described above, the first electrode plate Cst1 and the first transparent conductive layer 1ITO are disposed on the same layer.

In addition, it can be seen in conjunction with FIG. 4 and FIG. 11 that the first electrode plate Cst1 of the storage capacitor Cst in the white sub-pixel P1_W and the first electrode plate Cst1 of the storage capacitor Cst in the green sub-pixel P1_G are arranged in the first direction X, the first electrode plate Cst1 of the storage capacitor Cst in the red sub-pixel P1_R and the first electrode plate Cst1 of the storage capacitor Cst in the blue sub-pixel P1_B are arranged in the first direction X, the first electrode plate Cst1 of the storage capacitor Cst in the white sub-pixel P1_W and the first electrode plate Cst1 of the storage capacitor Cst in the red sub-pixel P1_R are arranged in the second direction Y, and the first electrode plate Cst1 of the storage capacitor Cst in the green sub-pixel P1_G and the first electrode plate Cst1 of the storage capacitor Cst in the blue sub-pixel P1_B are arranged in the second direction Y.

In some embodiments, a shape of the first electrode plate Cst1 is a rectangle with chamfered corners. The shape is illustratively described. Sizes of the first electrode plates Cst1 in different sub-pixels are the same or different. The sizes refer to areas of orthographic projections thereof on the substrate 01.

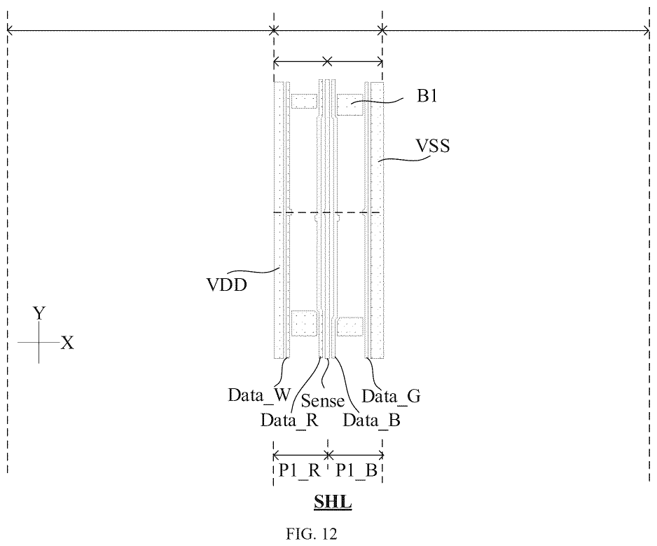

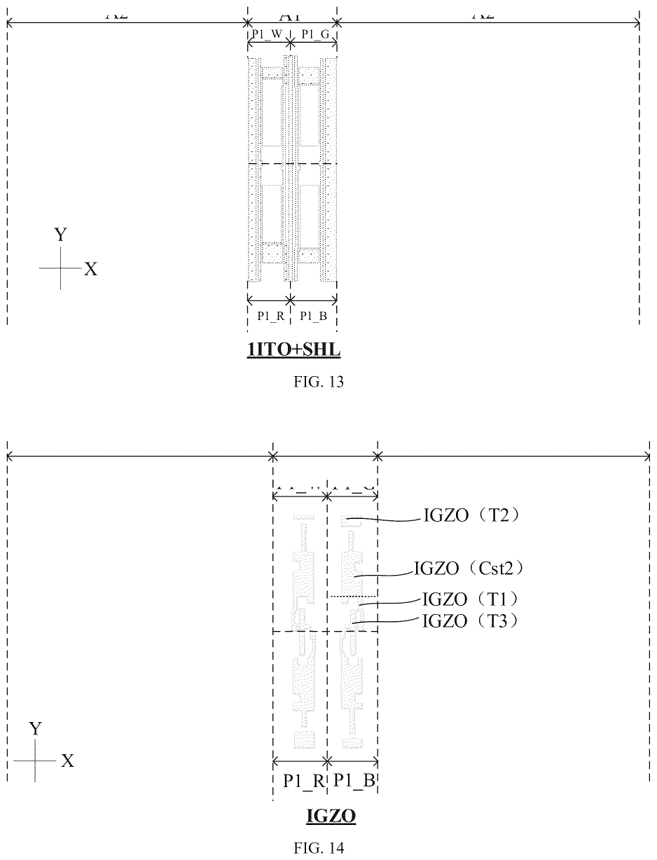

(2) Referring to FIG. 12, a structural layout of a light shielding layer SHL is illustrated. In conjunction with FIG. 11 and FIG. 12, FIG. 13 is a structural layout of a first transparent conductive layer 1ITO and a light shielding layer SHL in a display substrate.

It can be seen referring to FIG. 12 that the light shielding layer SHL is configured to form the sense line Sense, the first power line VDD, the second power line VSS, and the data line Data described above. The data line Data includes a data line Date_W for coupling to the white sub-pixel P1_W, a data line Date_G for coupling to the green sub-pixel P1_G, a data line Date R for coupling to the red sub-pixel P1_R, and a data line Date_B for coupling to the blue sub-pixel P1_B. that is, the sense line Sense, the first power line VDD, the second power line VSS, and the data line Data described above are disposed as a same layer as the light shielding layer SHL.

In addition, it can be seen in conjunction with FIG. 4 and FIG. 12 that the formed sense line Sense, the first power line VDD, the second power line VSS, and the data line Data are spaced apart in the first direction X. For arrangement, reference may be made to the above embodiments, which is not described again. In addition, each signal line extends in the second direction Y.

In some embodiments, each formed signal line is a straight or broken line of an equal width, or a straight or broken line of non-equal widths. The straight or broken line of variable-width is used to facilitate a layout of the pixel structure and reduce a parasitic capacitance on the signal line to ensure the reliability of the provided signal.

In addition, it can be seen referring to FIG. 12 that the light shielding layer SHL is further configured to form a light shielding portion B1 for shielding light leaked from the second transistor T2 (that is, the drive transistor generating the light-emitting drive signal), such that the intensity of light irradiated on the drive transistor is reduced, and the leakage current of the drive transistor is reduced. Thus, the impact on the characteristics of the drive transistor is reduced, and the drive transistor reliably generates the light-emitting drive signal to drive the light-emitting element 20 to emit light.

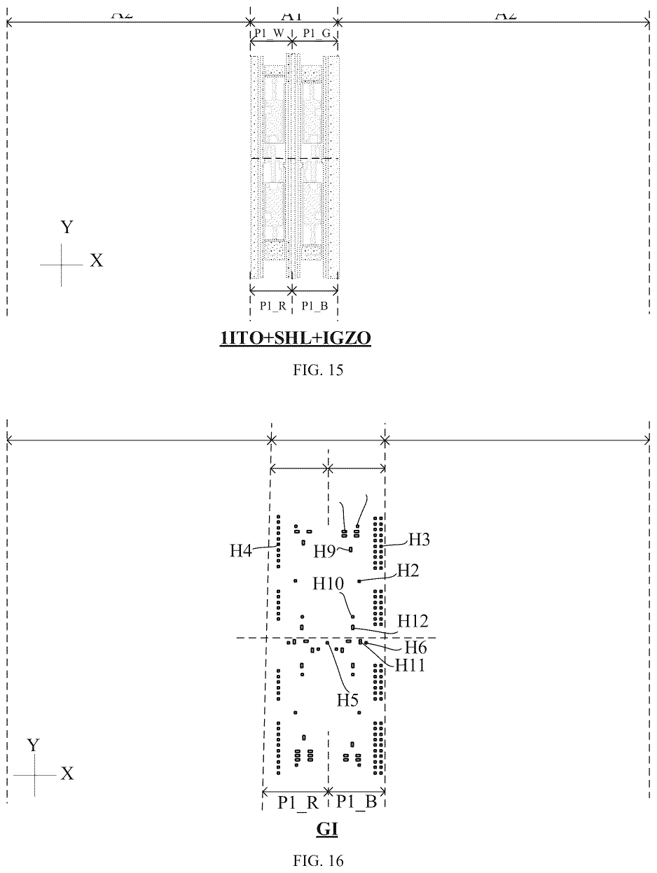

(3) Referring to FIG. 14, a structural layout of an active layer IGZO is illustrated. In conjunction with FIG. 13 and FIG. 14, FIG. 15 is a structural layout of a first transparent conductive layer 1ITO, a light shielding layer SHL, and an active layer IGZO.

It can be seen referring to FIG. 14 that the active layer IGZO is configured to form the active layer IGZO of the first transistor T1, the active layer IGZO of the second transistor T2, the active layer IGZO of the third transistor T3, and the second electrode plate Cst2 (that is, the second end of the storage capacitor Cst) of the storage capacitor Cst. As such, the active layer IGZO and the first transparent conductive layer 1ITO jointly compose the storage capacitor Cst.

For any sub-pixel, the active layer IGZO of the first transistor T1 and the active layer IGZO of the third transistor T3 are disposed on a same side as the second electrode plate Cst2 in the second direction Y, and the active layer IGZO of the second transistor T2 is disposed on an end portion of the second electrode plate Cst2 away from the same side. In addition, it can be seen referring to FIG. 15 that the active layer IGZO of the second transistor T2 is overlapped with the light shielding portion B1 formed by the light shielding layer SHL, such that the light shielding portion B1 reliably shields a channel region of the second transistor T2 to avoid the impact on the channel by the light, and thus the electrical performance of the second transistor T2 is protected.

In some embodiments, the active layer IGZO of the first transistor T1 and the active layer IGZO of the third transistor T3 are spaced apart in the first direction X. Active layers IGZO of first transistors T1 of two sub-pixels (for example, the white sub-pixel P1_W and the green sub-pixel P1_G) arranged in the first direction X are respectively disposed on different sides of active layers IGZO of third transistors T3 of the two sub-pixels. In addition, active layers IGZO of first transistors T1 of two sub-pixels (for example, the white sub-pixel P1_W and the red sub-pixel P1_R) arranged in the second direction Y are respectively disposed on different sides of active layers IGZO of third transistors T3 of the two sub-pixels.

In some embodiments, it can be seen referring to FIG. 14 that for any sub-pixel, the active layer IGZO of the formed first transistor T1 and the second electrode plate Cst2 are interconnected as an integrated structure. For any two sub-pixels arranged in the second direction Y, active layers IGZO of third transistors T3 thereof are interconnected as an integrated structure. As such, the space is saved, the connection structure is reduced, and the process is simplified.

In some embodiments, the active layer IGZO of the first transistor T1 and the active layer IGZO of the third transistor T3 are of an “I” structure, and the active layer IGZO of the second transistor T2 is in a rectangular shape, corners are chamfered, and the second electrode plate Cst2 is in an irregular shape shown in the drawing. The description is only illustrative shapes.

In some embodiments, it can be seen in conjunction with FIG. 14 and FIG. 15 that an orthographic projection of the active layer IGZO of the first transistor T1 on the substrate 01 is not overlapped with an orthographic projection of the first electrode plate Cst1 of the storage capacitor Cst on the substrate 01, and an orthographic projection of the active layer IGZO of the third transistor T3 on the substrate 01 is not overlapped with the orthographic projection of the first electrode plate Cst1 of the storage capacitor Cst on the substrate 01, such that an aspect ratio of the first transistor T1 and the third transistor T3 is facilitated to be designed.

In some embodiments, in two sub-pixels arranged in the first direction X, positions and shapes of the active layer IGZO of the first transistor T1 and the active layer IGZO of the third transistor T3 are basically mirror symmetric with respect to a vertical reference line, and positions of the active layer IGZO of the second transistor T2 are basically mirror symmetric with respect to the vertical reference line. In two sub-pixels arranged in the second direction Y, positions of the active layer IGZO of the second transistor T2 are basically mirror symmetric with respect to the vertical reference line. The vertical reference line is a straight line extending in the second direction Y and bisecting the display region in the first direction X.

In some embodiments, the active layer IGZO of each transistor includes a first region, a second region, and a channel region between the first region and the second region.

In some embodiments, the active layer IGZO is a single-layer structure, a double-layer structure, or a multi-layer structure.

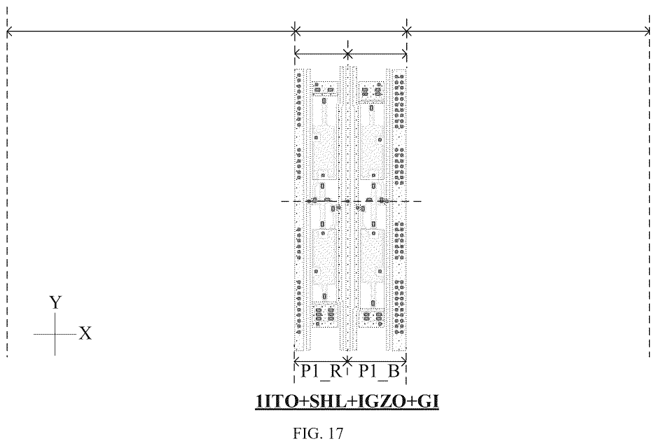

(4) Referring to FIG. 16, a structural layout of a gate insulative layer GI is illustrated. In conjunction with FIG. 15 and FIG. 16, FIG. 17 is a structural layout of a first transparent conductive layer 1ITO, a light shielding layer SHL, an active layer IGZO, and a gate insulative layer GI.

It can be seen referring to FIG. 16 that that the gate insulative layer GI is configured to form the second via H2 described in the above embodiments, and other several vias H3 to H11. In addition, in conjunction with FIG. 17, the following is acquired.

The second via H2 is configured to connect the first transparent conductive layer 1ITO of the first electrode plate Cst1 of the storage capacitor Cst to a subsequently formed gate metal layer GT to establish a channel Ch2 for entering the anode region.

An orthographic projection of the via H3 on the substrate 01 is overlapped with the orthographic projection of the second power line VSS on the substrate 01, and is configured to connect the subsequently formed gate metal layer GT to the second power line VSS. It can be further seen that a plurality of vias H3 are defined, and sequentially arranged in the first direction X and the second direction Y to improve the connection reliability.

An orthographic projection of the via H4 on the substrate 01 is overlapped with the orthographic projection of the first power line VDD on the substrate 01, and is configured to connect the subsequently formed gate metal layer GT to the first power line VDD. It can be further seen that a plurality of vias H4 are defined, and sequentially arranged in the second direction Y to improve the connection reliability.

An orthographic projection of the via H5 on the substrate 01 is overlapped with the orthographic projection of the sense line Sense on the substrate 01, and is configured to connect the subsequently formed gate metal layer GT to the sense line Sense.

An orthographic projection of the via H6 on the substrate 01 is overlapped with the orthographic projection of the data line Data on the substrate 01, and is configured to connect the subsequently formed gate metal layer GT to the data line Data.

An orthographic projection of the via H7 on the substrate 01 is overlapped with the orthographic projection of the light shielding portion B1 on the substrate 01, and is configured to connect the subsequently formed gate metal layer GT to the light shielding portion B1.

An orthographic projection of the via H8 on the substrate 01 is overlapped with the orthographic projection of the active layer IGZO of the second transistor T2 on the substrate 01, and is configured to connect the subsequently formed gate metal layer GT to the active layer IGZO of the second transistor T2. Vias H8 are organized into two sets arranged in the first direction X, and each set includes one via or two vias arranged in the second direction Y. One set of vias are configured to connect the gate metal layer GT to a first region of the active layer IGZO of the second transistor T2, and the other set of vias are configured to connect the gate metal layer GT to a second region of the active layer IGZO of the second transistor T2.

An orthographic projection of the via H9 on the substrate 01 is overlapped with the orthographic projection of the first electrode plate Cst1 of the storage capacitor Cst on the substrate 01, and is configured to connect the subsequently formed gate metal layer GT to the first electrode plate Cst1.

An orthographic projection of the via H10 on the substrate 01 is overlapped with the orthographic projection of the first electrode plate Cst1 of the storage capacitor Cst on the substrate 01, and is configured to connect the subsequently formed gate metal layer GT to the storage capacitor Cst.

An orthographic projection of the via H11 on the substrate 01 is overlapped with the orthographic projection of the active layer IGZO of the first transistor T1 on the substrate 01, and is configured to connect the subsequently formed gate metal layer GT to the active layer IGZO of the first transistor T1.

An orthographic projection of the via H12 on the substrate 01 is overlapped with the orthographic projection of the active layer IGZO of the third transistor T3 on the substrate 01, and is configured to connect the subsequently formed gate metal layer GT to the active layer IGZO of the third transistor T3. Two vias H12 are staggered, one of the two vias H12 is configured to connect the gate metal layer GT to the active layer IGZO of the second transistor T2, and the other of the two vias H12 is configured to connect the gate metal layer GT to the active layer IGZO of the third transistor T3.

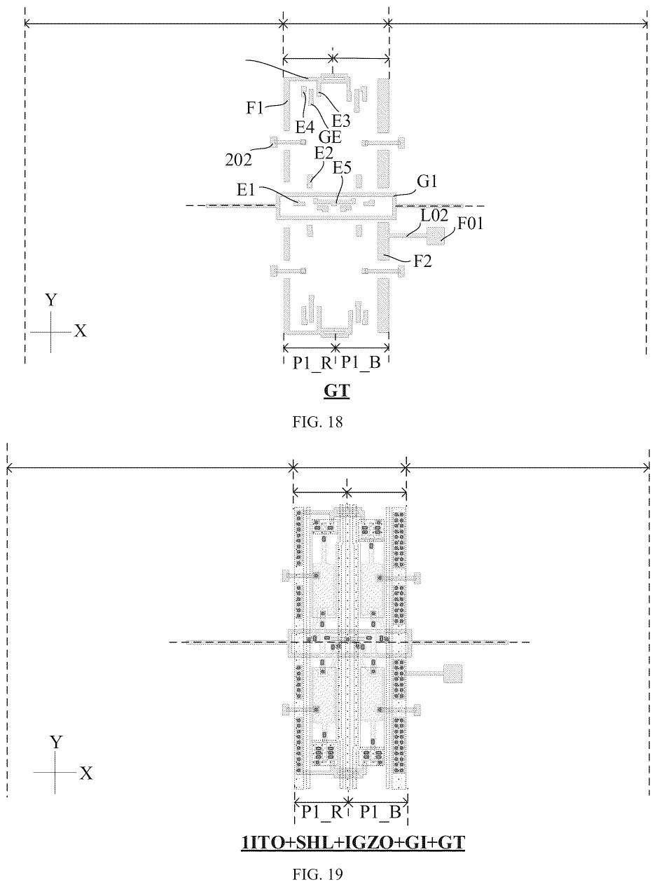

(5) Referring to FIG. 18, a structural layout of a gate metal layer GT is illustrated. In conjunction with FIG. 17 and FIG. 18, FIG. 19 is a structural layout of a first transparent conductive layer 1ITO, a light shielding layer SHL, an active layer IGZO, a gate insulative layer GI, and a gate metal layer GT.

It can be seen referring to FIG. 18 and FIG. 19 that the gate metal layer GT is configured to form the scan line G1. That is, the scan line G1 described in the above embodiments is disposed on a same layer as the gate metal layer GT. The scan line G1 is shared by the first transistors T1 and the third transistors T3 in four sub-pixels in one repeat unit 02.

In some embodiments, the scan line G1 is disposed in a central portion of the repeat unit 02, that is, is disposed between sub-pixels arranged in the second direction Y. For any of the first transistors T1 and the third transistors T3, an overlapped region of the scan line G1 and the active layer IGZO thereof is determined as a gate of the transistor, such that the scan line G1 controls the first transistors T1 and the second transistors T2 to be turned on or off.

In some embodiments, the scan line G1 extends in the first direction X, and includes an annular portion and a strip portion. The annular portion is disposed in the display region A1, and the strip portion is disposed in the transparent region A2.

In some embodiments, the annular portion includes two sub-lines extending in the first direction X, and the two sub-lines are arranged in the second direction Y. In the two sub-lines, one sub-line is connected to pixel circuits 10 in two sub-pixels (for example, the white sub-pixel P1_W and the green sub-pixel P1_G) in one pixel row arranged in the first direction X, and the other sub-line is connected to pixel circuits 10 in two sub-pixels (for example, the white sub-pixel P1_W and the blue sub-pixel P1_B) in another pixel row arranged in the first direction X, such that connection of double lines to the pixel circuits in the plurality of sub-pixels in the repeat unit is achieved. In addition, an orthographic projection of the one sub-line on the substrate 01 is at least partially overlapped with orthographic projections of the active layer IGZO of the first transistor T1 and the active layer IGZO of the third transistor T3 in the two connected sub-pixels on the substrate 01, overlapped regions are respectively determined as gates of the first transistor T1 and the third transistor T3, and the one sub-line is connected to the gate of the first transistor T1 and the gate of the third transistor T3 in the two connected sub-pixels. An orthographic projection of the other sub-line on the substrate 01 is at least partially overlapped with orthographic projections of the active layer IGZO of the first transistor T1 and the active layer IGZO of the third transistor T3 in the two connected sub-pixels on the substrate 01, and overlapped regions are respectively determined as gates of the first transistor T1 and the third transistor T3. That is, the other sub-line is connected to the gate of the first transistor T1 and the gate of the third transistor T3 in the two connected sub-pixels. As such, sub-lines transmitting the same scan signal simultaneously control all first transistors T1 and all third transistors T3 in four sub-pixels in the repeat unit to be turned on or off.

In some embodiments, the annular portion includes two sub-lines extending in the second direction Y and arranged in the first direction X, and the two sub-lines and the two sub-lines extending in the first direction X compose an annular structure. The annular structure is a rectangular annulus, or a polygonal annulus. The two sub-lines are respectively in one-to-one correspondence to the two strip sub-lines in the transparent region A2 to form a continuous scan line G1 extending in the first direction X.

In some embodiments, the two sub-lines extending in the first direction X are basically mirror symmetric with respect to the vertical reference line, and the two sub-lines extending in the second direction Y are basically mirror symmetric with respect to a horizontal reference line. The horizontal reference line is a straight line extending in the first direction X and bisecting the display region in the second direction Y, and is perpendicular to the vertical reference line.

In some embodiments, for a plurality of repeat units 02 sequentially disposed in the first direction X, a strip portion and an annular portion of the scan line G1 coupled to each repeat unit 02 are interconnected as an integrated structure, and strip portions and annular portions of the scan lines G1 coupled to the plurality of repeat units 02 are interconnected as an integrated structure.

In some embodiments, as described above, in at least one sub-pixel, one scan line G1 simultaneously controls the first transistor T1 and the third transistor T3 in the at least one sub-pixel to be turned on or off. In at least one pixel row, one scan line G1 simultaneously controls all first transistors T1 and all third transistors T3 in the at least one pixel row to be turned on or off. In at least one repeat unit 02, one scan line G1 simultaneously controls all first transistors T1 and all third transistors T3 in the at least one repeat unit 02 to be turned on or off.

In some embodiments, it can be seen in conjunction with FIG. 17 and FIG. 19 that the orthographic projections of the via H6, the via H11, the via H12, and the via H5 on the substrate 01 are within an orthographic projection of a region enclosed by the annular portion of the scan line G1 on the substrate 01.

In addition, it can be seen referring to FIG. 18 that the gate metal layer GT is further configured to form the connection electrode 202. That is, the connection electrode 202 described in the above embodiments is disposed on a same layer as the gate metal layer GT. The connection electrode 202 is in a strip shape extending in the first direction X, one end of the connection electrode 202 is connected to the first electrode plate Cst1 formed by the first transparent conductive layer 1ITO through the second via H2, and the other of the connection electrode 202 extends in a direction away from the sense line Sense to connect to the sequentially formed second transparent conductive layer 2ITO (that is, the first electrode 201 of the light-emitting element 20). The connection electrodes 202 of the two sub-pixels arranged in the second direction Y cross the first power line VDD. That is, an orthographic projection of the connection electrode 202 on the substrate 01 is overlapped with the orthographic projection of the first power line VDD on the substrate 01.

In some embodiments, the connection electrode 202 includes two connected portions, one portion is in a strip shape and is connected to the first electrode plate Cst1 through one end, and the other portion is in a rectangular shape and is connected to the first electrode 201 of the light-emitting element 20 though the other end. The strip portion crosses the first power line VDD.

In some embodiments, two portions in the connection electrode 202 are disposed in a same layer and are interconnected as an integrated structure.

In some embodiments, it can be seen referring to FIG. 18 that the gate metal layer GT is further configured to form a plurality of transfer electrodes E1 to E5, a gate electrode GE, a first power auxiliary line F1, a second power auxiliary line F2, a first power connection line L01, a second power connection line L02, and an auxiliary electrode F01.

The first power auxiliary line F1 is in a strip shape extending in the second direction Y, is disposed in the two sub-pixels (for example, the white sub-pixel P1_W and the red sub-pixel P1_R) arranged in the second direction Y, and is disposed on a side of the storage capacitor Cst in the first direction X. The first power auxiliary line F1 is connected to the first power line VDD through the via H4. The first power auxiliary line F1 and the first power line VDD form a double-line structure, such that the reliability of transmission of the power signal is ensured, a resistance of the first power line VDD is efficiently reduced, a voltage drop of the first power signal is efficiently reduced, and the display effect is great.

In some embodiments, the second power auxiliary line F2 is in a strip shape extending in the second direction Y, is disposed in the other two sub-pixels (for example, the green sub-pixel P1_G and the blue sub-pixel P1_B) arranged in the second direction Y, and is disposed on a side of the storage capacitor Cst in the first direction X. The second power auxiliary line F2 is connected to the second power line VSS through the via H3. The second power auxiliary line F2 and the second power line VSS form a double-line structure, such that the reliability of transmission of the power signal is ensured, a resistance of the second power line VSS is efficiently reduced, a voltage drop of the second power signal is efficiently reduced, and the display effect is great.

In some embodiments, the first power connection line L01 is in a strip shape extending in the first direction X. A main portion of the first power connection line L01 is disposed in the two sub-pixels (for example, the white sub-pixel P1_W and the green sub-pixel P1_G) arranged in the first direction X, and is disposed on a side, away from the scan line G1, of the storage capacitor Cst of the sub-pixel.

In the white sub-pixel P1_W, a first end of the first power connection line L01 is connected to the first power auxiliary line F1 in the white sub-pixel P1_W, a second end of the first power connection line L01 extends to the green sub-pixel P1_G in the first direction X, and the first power auxiliary line F1 is connected to the transfer electrodes in the white sub-pixel P1_W and the green sub-pixel P1_G.

In the red sub-pixel P1_R, the first end of the first power connection line L01 is connected to the first power auxiliary line F1 in the red sub-pixel P1_R, the second end of the first power connection line L01 extends to the blue sub-pixel P1_B in the first direction X, and the first power auxiliary line F1 is connected to the transfer electrodes in the red sub-pixel P1_R and the blue sub-pixel P1_B.

In some embodiments, the first power connection line L01 achieves a one-drag-four structure of the first power line VDD in the repeat unit 02, such that the number of signal lines is saved, the occupied space is reduced, the structure is simple, the layout is reasonable, the layout space is fully used, the utilization rate of space is improved, and the resolution and transparency are improved.

In some embodiments, in the overlapped region of the first power connection line L01 and the sense line Sense, strip openings (vias) extending in the first direction X are defined in the first power connection line L01, such that the region is in an annular structure to reduce an area of the overlapped region of the first power connection line L01 and the data line Data and the sense line Sense, reduce the parasitic capacitance between signal lines, and improve the display effect In some embodiments, the first power connection line L01 of the white sub-pixel P1_W and at least one first power auxiliary line F1 are interconnected as an integrate structure, and the first power connection line L01 of the red sub-pixel P1_R and at least one first power auxiliary line F1 are interconnected as an integrate structure.

In some embodiments, the second power connection line L02 and the auxiliary electrode F01 are disposed in the transparent region A2 of the repeat unit 02. The second power connection line L02 is in a strip shape, a first end of the second power connection line L02 is connected to the second power auxiliary line F2, and a second end of the second power connection line L02 extends to the direction of the transparent region A2 and is then connected to the auxiliary electrode F01.

In some embodiments, the auxiliary electrode F01 is in a rectangular shape, and is configured to connect to another subsequently formed auxiliary electrode. The another auxiliary electrode is configured to connect to the subsequently formed second electrode 203 (that is, the cathode of the light-emitting element 20), such that the second power line VSS and the second electrode 203 are connected.

In some embodiments, one second power connection line L02 and one auxiliary electrode F01 are disposed, and are disposed in the transparent region A2 near the blue sub-pixel P1_B. Alternatively, a plurality of second power connection lined L02 and a plurality of auxiliary electrodes F01 that are in one-to-one correspondence are disposed in different positions, extending lengths of the plurality of second power connection lined L02 in the first direction X are the same or different, and areas of the plurality of auxiliary electrodes F01 are the same or different,.

In some embodiments, the second power auxiliary line F2 and the auxiliary electrode F01 that are connected through the second power connection line L02 are interconnected as an integrate structure.

In some embodiments, due to the voltage (IR) drop in large-sized transparent displays, the second power line VSS for transmitting the low potential second power signal is disposed in each repeat unit 02 in the embodiments of the present disclosure, and the second power line VSS is connected to the cathode of the subsequently formed light-emitting element 20 via the auxiliary electrode, such that the voltage drop of the second power signal is effectively reduced, the voltage drop problem of the large-sized transparent display is effectively solved, and the uniformity of the display is ensured.

In some embodiments, positions and shapes of the first power auxiliary line F1 and the first power connection line L01 in the white sub-pixel P1_W and positions and shapes of the first power auxiliary line F1 and the first power connection line L01 in the red sub-pixel P1_R are basically mirror symmetric with respect to the horizontal reference line. The positions and the shape of the second power auxiliary line F2 in the green sub-pixel P1_G and the position and the shape of the second power auxiliary line F2 in the blue sub-pixel P1_B are basically mirror symmetric with respect to the horizontal reference line. The position of the first power auxiliary line F1 in the white sub-pixel P1_W and the position of the second power auxiliary line F2 in the green sub-pixel P1_G are basically mirror symmetric with respect to the vertical reference line, and the position of the first power auxiliary line F1 in the red sub-pixel P1_R and the position of the second power auxiliary line F2 in the blue sub-pixel P1_B are basically mirror symmetric with respect to the vertical reference line.

In some embodiments, the gate electrode GE is in a strip shape extending in the second direction Y, and is close to a side of the first power line VDD. One end of the gate electrode GE is connected to the second electrode plate Cst2 of the storage capacitor Cst, the other end of the gate electrode GE extends in the direction away from the scan line G1, and an orthographic projection of the gate electrode GE on the substrate 01 is at least partially overlapped with the orthographic projection of the active layer IGZO of the second transistor T2 on the substrate 01. The gate electrode GE is determined as the gate of the second transistor T2, and controls the second transistor T2 to be turned on or off.

In some embodiments, the transfer electrode E1 is in a rectangular shape, one end of the transfer electrode E1 is connected to the active layer IGZO of the first transistor T1 through the via H11, and the other end of the transfer electrode E1 is connected to the data line Data through the via H6. The transfer electrode E1 is determined as the first electrode of the first transistor T1, such that the data line Data writes the data signal to the first electrode of the first transistor T1. In some embodiments, the data line Data includes the date line for coupling to the white sub-pixel P1_W, the data line Date_G for coupling to the green sub-pixel P1_G, the data line Date R for coupling to the red sub-pixel P1_R, and the data line Date_B for coupling to the blue sub-pixel P1_B.

In some embodiments, the transfer electrode E2 is in a strip shape extending in the second direction Y, one end of the transfer electrode E2 is connected to the first electrode plate Cst1 through the via H10, and the other end of the transfer electrode E2 is connected to the active layer IGZO of the third transistor T3 through the via H12. The transfer electrode E2 is determined as the second electrode of the third transistor T3, such that the second electrode of the third transistor T3 and the first electrode plate Cst1 have the same potential.

In some embodiments, the transfer electrode E3 is in a strip shape extending in the second direction Y, one end of the transfer electrode E3 is connected to the active layer IGZO of the second transistor T2 through the via H8, and the other end of the transfer electrode E3 is connected to the first power connection line L01. The transfer electrode E3 is determined as the first electrode of the second transistor T2. As the first power connection line L01 is connected to the first power auxiliary line F1, and the first power auxiliary line F1 is connected to the first power line VDD, the first power signal supplied over the first power line VDD is written to the first electrode of the second transistor T2.

In some embodiments, the transfer electrode E3 of the white sub-pixel P1_W, the transfer electrode E3 of the green sub-pixel P1_G, and the connected first power connection line L01 are interconnected as an integrated structure, and the transfer electrode E3 of the red sub-pixel P1_R, the transfer electrode E3 of the blue sub-pixel P1_B, and the connected first power connection line L01 are interconnected as an integrated structure.

In some embodiments, the transfer electrode E4 is in a strip shape extending in the second direction Y, one end of the transfer electrode E4 is connected to the active layer IGZO of the second transistor T2 through the via H8, and the other end of the transfer electrode E4 is connected to the first electrode plate Cst1 of the storage capacitor Cst through the via H7. The transfer electrode E4 is determined as the second electrode of the second transistor T2, such that the second electrode of the second transistor T2 and the first electrode plate Cst1 have the same potential.

In some embodiments, the transfer electrode E5 is in a strip shape extending in the first direction X, one end of the transfer electrode E5 is connected to the active layer IGZO of the third transistor T3 through the via H11, and the other end of the transfer electrode E5 is connected to the sense line Sense through the via H5. The transfer electrode E5 is determined as the first electrode of the third transistor T3, such that the signal supplied over the sense line Sense is written to the first electrode of the third transistor T3.

In some embodiments, as in the two sub-pixels in the pixel column adjacent in the second direction Y, the active layers IGZO of the third transistors T3 are interconnected as an integrated structure, and the two sub-pixels share the active layer IGZO of the third transistor T3, the two sub-pixels share a same transfer electrode E5.

In some embodiments, transfer electrodes E5 in two pixel columns are interconnected as an integrated structure, and compose a connection line of the sense lines Sense. That is, the pixel circuits 10 of four sub-pixels in the display region A1 share the connection line of the sense line Sense, such that a one-drag-six structure of the sense line Sense in the repeat unit 02 is achieved. As such, the number of signal lines is saved, the occupied space is reduced, the structure is simple, the layout is reasonable, the layout space is fully used, the utilization rate of space is improved, and the resolution and transparency are improved.

In some embodiments, as the sense line Sense is disposed between two pixel columns, is connected to the third transistors T3 in the sub-pixels in the two pixel columns via the transfer electrodes E5, and the third transistors T3 in the two sub-pixels arranged in the first direction X are symmetric with respect to the sense line Sense, the symmetric structure ensures that delays of the sense signals in writing in the third transistors T3 are basically the same, and thus the uniformity of the display is ensured.

In some embodiments, an orthographic projection of the transfer electrodes E1 on the substrate 01 and an orthographic projection of the transfer electrodes E5 on the substrate 01 are within the orthographic projection of the region enclosed by the annular portion of the scan line G1 on the substrate 01.

In some embodiments, for other portions formed by the gate metal layer GT, positions of patterns in the white sub-pixel P1_W and positions of patterns in the red sub-pixel P1_R are basically mirror symmetric with respect to the horizontal reference line, positions of patterns in the green sub-pixel P1_G and positions of patterns in the blue sub-pixel P1_B are basically mirror symmetric with respect to the horizontal reference line, positions of patterns in the white sub-pixel P1_W and positions of patterns in the green sub-pixel P1_G are basically mirror symmetric with respect to the vertical reference line, and positions of patterns in the red sub-pixel P1_R and positions of patterns in the blue sub-pixel P1_B are basically mirror symmetric with respect to the vertical reference line.

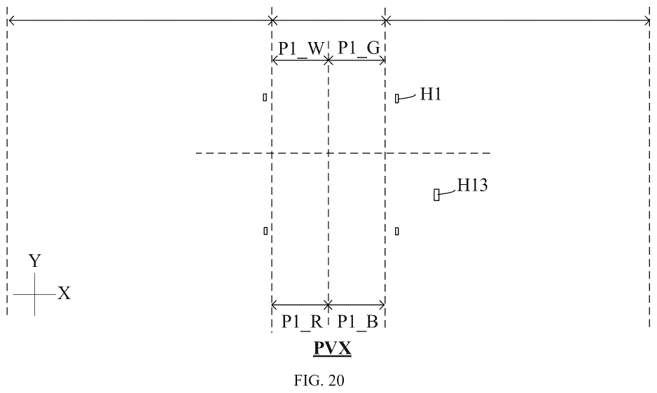

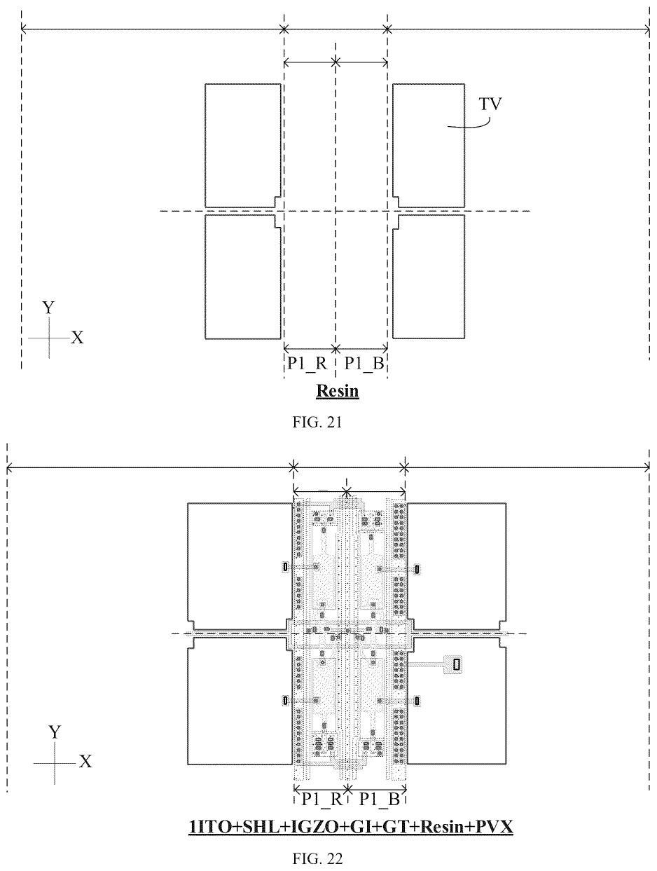

(6) Referring to FIG. 20, a structural layout of a passivation layer PVX is illustrated. Referring to FIG. 21, a structural layout of a planarization layer Resin is illustrated. In conjunction with FIG. 19, FIG. 20, and FIG. 21, FIG. 22 is a structural layout of a first transparent conductive layer 1ITO, a light shielding layer SHL, an active layer IGZO, a gate insulative layer GI, a gate metal layer GT, a passivation layer PVX, and a planarization layer Resin.

It can be seen referring to FIGS. 20 to 22 that the passivation layer PVX is configured to form the first via H1 described in the above embodiments, and is further configured to form the via H13.

An orthographic projection of the first via H1 on the substrate 01 is overlapped with an orthographic projection of the other end of the connection electrode 202 on the substrate 01, and the first via H1 is configured to connect the connection electrode 202 to a portion, as the anode of the light-emitting element 20, of the subsequently formed second transparent conductive layer 2ITO.

The via H13 is located in the transparent region A2, an orthographic projection of the via H13 on the substrate 01 is overlapped with an orthographic projection of the auxiliary electrode F01 on the substrate 01, and the via H13 is configured to connect the auxiliary electrode F01 to the subsequently formed second electrode 203 (that is, the cathode of the light-emitting element 20).

In some embodiments, an area of the orthographic projection of the via H13 on the substrate 01 is greater than an area of the orthographic projection of the first via H1 on the substrate 01.

In some embodiments, a plurality of planarization openings TV are defined in the planarization layer Resin, the planarization opening TV is in a rectangular shape, and corners of the rectangle have grooves or chamfers. The auxiliary electrode F01 and a portion of the connection electrode 202 connected to the first electrode 201 of the light-emitting element 20 are within the planarization opening TV.

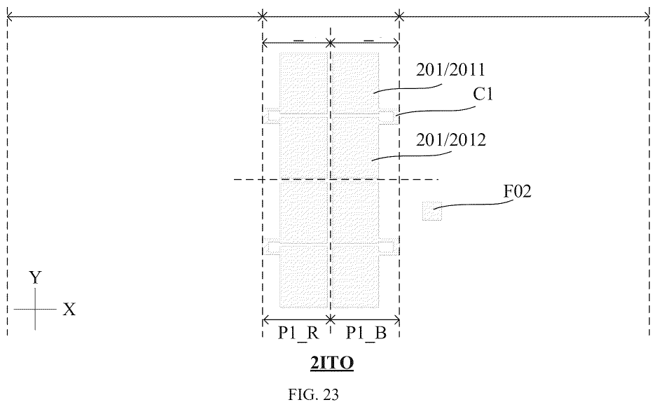

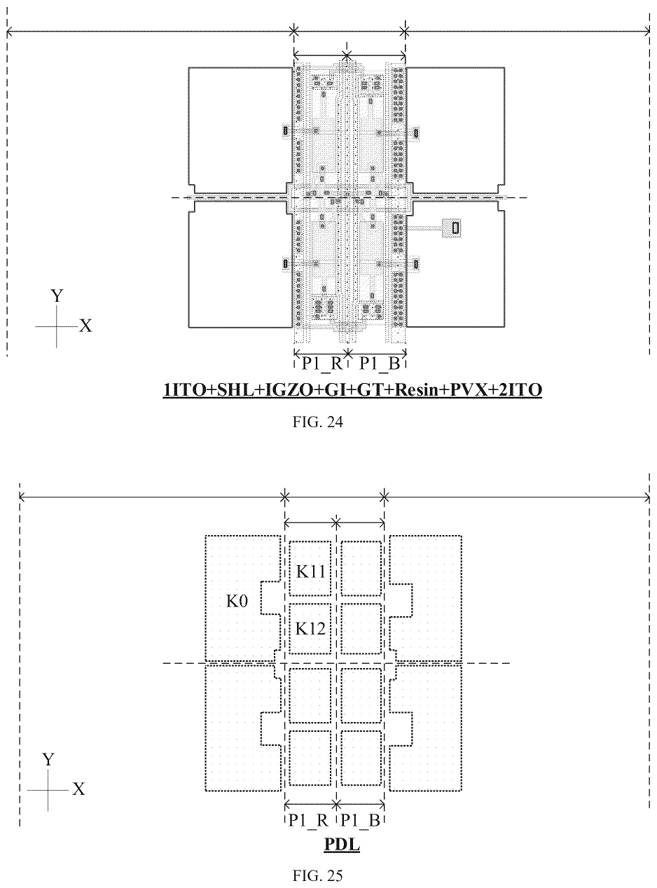

(7) Referring to FIG. 23, a structural layout of a second transparent conductive layer 2ITO is illustrated. In conjunction with FIG. 22 and FIG. 23, FIG. 24 is a structural layout of a first transparent conductive layer 1ITO, a light shielding layer SHL, an active layer IGZO, a gate insulative layer GI, a gate metal layer GT, a passivation layer PVX, a planarization layer Resin, and a second transparent conductive layer 2ITO.

It can be seen referring to FIG. 23 and FIG. 24 that the second transparent conductive layer 2ITO is configured to form the first electrode 201 of the light-emitting element 20, and the first electrode 201 is the anode of the light-emitting element 20. That is, the first electrode 201 described above is disposed as a same layer as the second transparent conductive layer 2ITO.

In some embodiments, the first electrode 201 includes a first sub-electrode 2011 and a second sub-electrode 2012 that are spaced apart. The first sub-electrode 2011 and the second sub-electrode 2012 are in a rectangular shape, and are sequentially arranged in the second direction Y.

In some embodiments, the first electrode 201 further includes a “C-shaped” portion (denoted as C1). The portion C1 is connected to the first sub-electrode 2011 and the second sub-electrode 2012, and is connected to the connection electrode 202 formed by the gate metal layer GT through the first via H1, such that the first sub-electrode 2011 is connected to the second sub-electrode 2012. As the portion C1 is further connected to the connection electrode 202, and the connection electrode 202 is connected to the first electrode plate Cst1 of the storage capacitor Cst, the first electrode 201 and the first electrode plate Cst1 have the same potential.

In some embodiments, in the case that the display substrate has a poor bright spot, the “C-shaped” portion C1 is truncated by laser cutting, such that one of the first sub-electrode 2011 and the second sub-electrode 2012 is connected to the first electrode plate 11, and the other of the first sub-electrode 2011 and the second sub-electrode 2012 is floating. Thus, the poor bright spot is quickly repaired.

In some embodiments, four first electrodes 201 in the repeat unit 02 are arranged in a square shape. The first electrode 201 in the upper left is connected to the pixel circuit 10 in the white sub-pixel P1_W, the first electrode 201 in the upper right is connected to the pixel circuit 10 in the green sub-pixel P1_G, the first electrode 201 in the lower left is connected to the pixel circuit 10 in the red sub-pixel P1_R, and the first electrode 201 in the lower right is connected to the pixel circuit 10 in the blue subpixel P1_B. In some embodiments, the arrangement of the first electrodes 201 is adjusted according to actual needs, which is not limited herein in the present disclosure.

In some embodiments, the first sub-electrode 2011, the second sub-electrode 2012, and the “C-shaped” portion C1 are interconnected as an integrated structure.

In some embodiments, the second transparent conductive layer 2ITO is further configured to form another auxiliary electrode F02. The auxiliary electrode F02 is disposed in the transparent regions of the red sub-pixel P1_R and the blue subpixel P1_B on a side of the first direction X.

In some embodiments, the auxiliary electrode F02 is in a rectangular shape. An orthographic projection of the auxiliary electrode F02 on the substrate 01 is at least partially overlapped with the orthographic projection of the auxiliary electrode F01 on the substrate 01, and the auxiliary electrode F02 is connected to the auxiliary electrode F01 through the via H13, and is configured to connect to the subsequently formed second electrode 203.

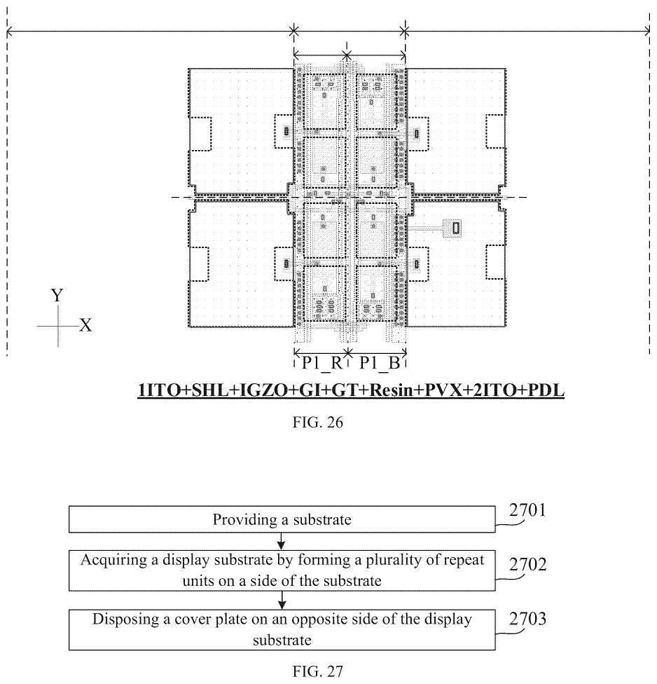

(8) Referring to FIG. 25, a structural layout of a pixel definition layer PDL is illustrated. In conjunction with FIG. 24 and FIG. 25, FIG. 26 is a structural layout of a first transparent conductive layer 1ITO, a light shielding layer SHL, an active layer IGZO, a gate insulative layer GI, a gate metal layer GT, a passivation layer PVX, a planarization layer Resin, a second transparent conductive layer 2ITO, and a pixel definition layer PDL.

It can be seen referring to FIG. 25 and FIG. 26 that the first opening K11 and the second opening K12 are defined in the pixel definition layer PDL, and a transparent opening KO is also defined in the pixel definition layer PDL.

The first opening K11 and the second opening K12 are disposed in the display region A1, an orthographic projection of the first opening K11 on the substrate 01 is overlapped with the orthographic projection of the first sub-electrode 2011 in the first electrode 201 on the substrate 01, and an orthographic projection of the second opening K12 on the substrate 01 is overlapped with the orthographic projection of the second sub-electrode 2012 in the first electrode 201 on the substrate 01. The transparent opening KO is disposed in the transparent region A2, a groove is defined in a side of the transparent opening KO close to the display region A1, and a connection portion (that is, the first via H1) of the first electrode 201 and the connection electrode 202 is also disposed in the groove, such that the pixel definition layer PDL shields the first via H1 to avoid light leakage.

In some embodiments, shapes of the first opening K11 and the second opening K12 are similar to a shape of the sub-electrode.

It should be noted that as described above, the display substrate 0 further includes a light-emitting layer EL and a second electrode 203 (that is, the cathode of the light-emitting element 20) that are sequentially laminated in a side, away from the substrate 01, of the pixel definition layer PDL, and the layouts are not shown. The display panel further includes a formed color film layer and a black matrix layer.

In some embodiments, the substrate 01 is a flexible substrate 01, or a rigid substrate 01. The rigid substrate is, but is not limited to, one or more of glass or quartz, and the flexible substrate is, but is not limited to, one or more of polyethylene glycol terephthalate, glycol terephthalate, polyether-ether-ketone, polystyrene, polycarbonate, polyaryl ester, polyarylate, polyimide, polyvinyl chloride, polyethylene, textile fiber.

In some embodiments, the flexible substrate 01 includes a first flexible material layer, a first inorganic material layer, an active layer, a second flexible material layer, and a second inorganic material layer that are sequentially laminated. The first flexible material layer and the second flexible material layer are made of a material, such as polyimide, polyethylene glycol terephthalate, or a surface-treated polymer soft film. The material of the first inorganic material layer and the second inorganic material layer are silicon nitride or silicon oxide to improve the water oxygen resistance of the substrate 01.

It can be seen from the above description that in the embodiments of the present disclosure, the anode of the light-emitting element 20 is lapped with the first electrode plate Cst1 of the storage capacitor Cst through the gate metal layer GT based on the pixel circuit 10 of a 3T1C structure. The first electrode plate Cst1 is formed by the first transparent conductive layer 1ITO to form a transparent capacitor, such that the double-sides emission of the top and bottom faces is achieved, and the product is optimized. In addition, longitudinal wiring is achieved using the light shielding layer SHL, transverse wiring is achieved using the gate metal layer GT, such that the full signal repairability and high transparency effect are achieved.

It should be noted that film layer materials, shapes, layouts, and sizes described in the above embodiments are only illustrative.

In summary, the embodiments of the present disclosure provide a display panel. The display panel includes a substrate, and a plurality of repeat units on the substrate. The repeat unit is divided into a display region and a transparent region, and includes sub-pixels in the display region. The sub-pixel includes a pixel circuit and a light-emitting element that are coupled. The pixel circuit is configured to drive the light-emitting element to emit light, and includes a storage capacitor. In the display substrate, for a first electrode plate and a second electrode plate that are overlapped in the storage capacitor, the first electrode plate is connected to a first electrode of the light-emitting element via a transfer electrode. The first electrode plate and the first electrode are both made of a transparent conductive material, and are overlapped with an opening in the display region. As such, on the premise that the first electrode plate and the first electrode are reliably coupled at all portions thereof to ensure that the light-emitting element is reliably driven to emit light, double-sided light emission is achieved based on the transparent capacitor, and thus a display effect is great.

FIG. 27 is a flowchart of a method for manufacturing a display panel according to some embodiments of the present disclosure. The method is applicable to manufacturing the display panel in the above embodiments. The method includes:

S2701, a substrate is provided.

S2702, a display substrate is acquired by forming a plurality of repeat units on a side of the substrate.

S2703, a cover plate is disposed on an opposite side of the display substrate.

The formed repeat unit is divided into a display region and a transparent region on at least one side of the display region, and includes a plurality of sub-pixels in the display region. The sub-pixel includes a pixel circuit and a light-emitting element that are coupled. The pixel circuit is configured to drive the light-emitting element to emit light.

The first electrode plate, the transfer electrode, the first electrode, and the second electrode plate are disposed in different layers, a material of the first electrode plate and a material of the first electrode both include a transparent conductive material. At least one opening is defined in the display region. The orthographic projection of the first electrode plate on the substrate and an orthographic projection of the first electrode on the substrate are both overlapped with an orthographic projection of the at least one opening on the substrate.

That is, in some optional implementation:

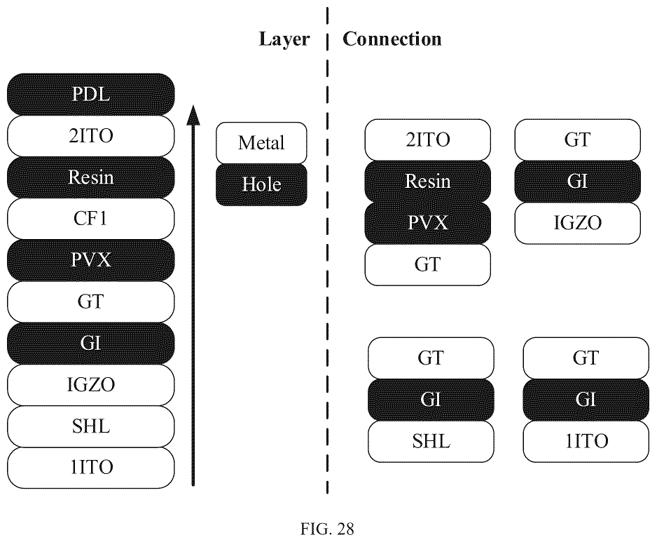

It can be seen in conjunction with FIG. 1 and the flowchart shown in FIG. 28 that the formed display substrate 0 includes the following layers: a substrate 01, and a first transparent conductive layer 1ITO, a light shielding layer SHL, an active layer IGZO, a gate insulative layer GI, a gate metal layer GT, a passivation layer PVX, a first color filter layer CF1, a planarization layer Resin, a second transparent conductive layer 2ITO, a pixel definition layer PDL, a light-emitting layer EL, and a second electrode 203 that are disposed between the substrate 01 and the cover plate 1 and sequentially laminated in the direction away from the substrate 01. FIG. 28 only illustratively shows the first transparent conductive layer 1ITO to the pixel definition layer PDL that are sequentially laminated.

The conductive film layers (for example, the metal layer) are connected through the vias.

For example, referring to the connection shown in FIG. 28, the gate metal layer GT is connected to the light shielding layer SHL and the first transparent conductive layer 1ITO through the via running through the gate insulative layer GI, the second transparent conductive layer 2ITO is connected to the gate metal layer GT through the via running through the passivation layer PVX and the planarization layer Resin, and the gate metal layer GT is connected to the active layer IGZO through the via running through the gate insulative layer GI.

In some embodiments, the opening includes a top-emission opening and a bottom-emission opening that are opposite to each other. The top-emission opening is disposed in a side of the cover plate, and the bottom-emission opening is disposed in a side of the display substrate. The method further includes forming a reflection electrode on a side, away from the substrate, of the first electrode.

An orthographic projection of the formed reflection electrode on the substrate is overlapped with an orthographic projection of the bottom-emission opening on the substrate, and is not overlapped with an orthographic projection of the top-emission opening on the substrate.

That is, in some optional implementation:

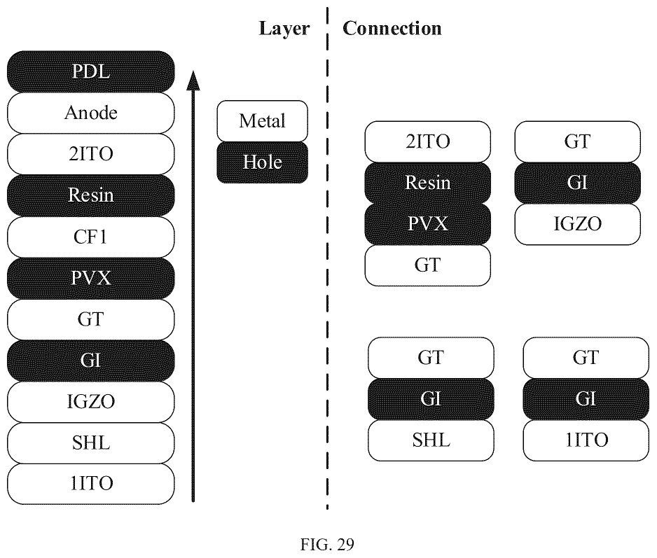

It can be seen in conjunction with FIG. 10 and the flowchart shown in FIG. 29 that in addition to the film layer shown in FIG. 28, the formed display substrate 0 further includes a reflection electrode, also referred to as a reflection anode, between the second transparent conductive layer 2ITO and the pixel definition layer PDL. The reflection electrode is disposed to increase the luminescence yield of the top-emission, and thus the display effect is great.

Compared with FIG. 28 and FIG. 29, it can be seen that in addition to the first color filter layer CF1, nine masks are used to manufacture the display substrate based on the structure shown in FIG. 28. The passivation layer PVX and the planarization layer Resin are formed simultaneously using a halftone Mask to reduce to eight masks. On the basis of the structure shown in FIG. 29, an additional process for preparing the reflection anode is needed, that is, nine masks are used to manufacture the display substrate.

It should be noted that various film layers are prepared using the patterning process in the above embodiments, which are not repeated herein.

In summary, the embodiments of the present disclosure provide a method for manufacturing a display panel. The formed display panel includes a substrate, and a plurality of repeat units on the substrate. The repeat unit is divided into a display region and a transparent region, and includes sub-pixels in the display region. The sub-pixel includes a pixel circuit and a light-emitting element that are coupled. The pixel circuit is configured to drive the light-emitting element to emit light, and includes a storage capacitor. In the display substrate, for a first electrode plate and a second electrode plate that are overlapped in the storage capacitor, the first electrode plate is connected to a first electrode of the light-emitting element via a transfer electrode. The first electrode plate and the first electrode are both made of a transparent conductive material, and are overlapped with an opening in the display region. As such, on the premise that the first electrode plate and the first electrode are reliably coupled at all portions thereof to ensure that the light-emitting element is reliably driven to emit light, double-sided light emission is achieved based on the transparent capacitor, and thus a display effect is great.

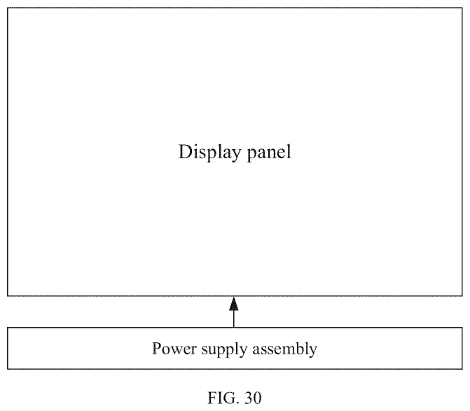

FIG. 30 is a schematic structural diagram of a display device according to some embodiments of the present disclosure. as shown in FIG. 30, the display device includes a power supply assembly, and the display panel in the above embodiments.

The power supply assembly is connected to the display panel, and is configured to supply power to the display panel.

As the display device achieves basically the same technical effects as the display panel in the above embodiments, and thus the technical effects of the display device are not repeated herein for brevity.

In some embodiments, the display device is an OLED display device, a quantum light-emitting diode (QLED) display device, or an active-matrix organic light-emitting diode (AMOLED) display device.

In some embodiments, the display device includes a mobile phone, a tablet computer, a television, a monitor, a laptop computer, a digital photo frame, a navigator, and any other product or component with a display function, and the present embodiment is not limited to this.

With the increasing development of display technology, the OLED technology is more and more applied to the transparent display. The transparent display is an important personalized display field of the display technology, and refers to the image display in the transparent state. The viewer can see the image in the display device and the scene behind the display device, and thus virtual reality (VR), augmented reality (AR), and 3D display function are achieved. A transparent display device using the OLED technology generally divides each sub-pixel into a display region and a transparent region, the display region is provided with a pixel circuit 10 and a light-emitting element to display images, and the transparent region achieves light transmission and is adaptable to the display panel described in the embodiments of the present disclosure.

It should be noted that the terms used in the embodiments of the present disclosure are only intended to explain the embodiments, and are not intended to limit the present disclosure. Unless otherwise defined, technical or scientific terms used in the embodiments of the present disclosure shall have ordinary meaning understood by persons of ordinary skill in the art to which the disclosure belongs.

For example, the terms “first,” “second,” “third,” and the like used in the description and claims of the present disclosure are not intended to indicate any order, quantity or importance, but are merely used to distinguish the different components.

Similarly, the terms “a,” “an,” and the like are not intended to limit the quantity, and only represent that at least one exists.

The terms “comprise,” “include,” and the like are used to indicate that the element or object preceding the terms covers the element or object following the terms and its equivalents, and shall not be understood as excluding other elements or objects.

For convenience, phases indicating orientation or positional relationships by the terms “center,” “upper,” “lower,” “front,” “rear,” “vertical,” “horizontal,” “top,” “bottom,” “inner,” “outer,” and the like compose positional relationships of the elements with reference to the description of the accompanying drawings, are merely intended to describe the present disclosure and simplify the description, do not indicate or imply specific orientation, and structured and operation in the specific orientation of the described device or element, and therefore, should not be constructed as limitations to the present disclosure. The positional relationships of the elements change appropriately according to the directions of the elements, and thus are not limited to the words in the description and can be appropriately replaced according to the circumstances.

The proportions of the accompany drawings in the present disclosure may be used as a reference in actual processes, but are not limited to this. For example, a width to the length ratio of the channel, the thicknesses and spaces of various film layers, and the widths and spaces of various signal lines can be adjusted according to actual needs. The number of pixels in the display substrate and the number of sub-pixels in each pixel are not limited to the number shown in the accompany drawings, the accompany drawings described in the present disclosure are only structural diagrams, and implementations of the present disclosure are not limited to the shapes or values shown in the accompany drawings.

In the embodiments of the present disclosure, unless otherwise specified and limited, it should be noted that the terms “disposed,” “coupled to,” and “connected to” need to be broadly understood, for example, connection may be fixed connection, detachable connection or integrated connection; or may be mechanical connection, or electrical connection; or may be direct connection, or indirect connection via an intermediation, or internal communication of two elements. Those of ordinary skill in the art can understand the specific meaning of the above terms in the present disclosure in accordance with specific conditions.

In the embodiments of the present disclosure, the transistor is a component including at least three terminals: the gate, the drain and the source. In the transistor, a channel region is disposed between the drain (the drain terminal, the drain region, or the drain electrode) and the source (the source terminal, the source region, or the source electrode), and the current can flow via the drain, the channel region, and the source. It should be noted that in the description, the channel region refers to a region that the current mainly flows.

In the embodiments of the present disclosure, the first electrode is a drain, and the second electrode is a source. Alternatively, the first electrode is a source, and the second electrode is a drain. In the case of transistors with opposite polarity are used, or the direction of the current in circuit changes, the functions of the “source” and the “drain” are exchangeable. Thus, in the description, the “source” and the “drain” are exchangeable, and the “source terminal” and the “drain terminal” are exchangeable.

In the embodiments of the present disclosure, the “electrical connection” includes a case that elements are connected by elements having an electrical action. The “component having an electrical action” have no special limitation as long as they can transmit and receive the electrical signals between the connected elements. Examples of “components having an electrical action” include electrodes and lines, and also include switch components such as transistors, resistors, inductors, capacitors, and other components with various functions.

In the embodiments of the present disclosure, the term “parallel” means a state where an angle formed by two lines is more than −10° and less than 10°, and thus including an angle more than −5° and less than 5°. In addition, the term “vertical” refers to a state where an angle formed by two lines is more than 80° and less than 100°, and thus including an angle more than 85° and less than 95°.

In the embodiments of the present disclosure, the terms “film” and “layer” are exchangeable. For example, the “conductive layer” is replaced by the “conductive film.” Similarly, the “insulative film” is replaced by the “insulative layer.”

In the embodiments of the present disclosure, triangles, rectangles, trapezoids, pentagons, hexagons, and the like are not strictly defined, and may be approximately triangles, rectangles, trapezoids, pentagons or hexagons, and the like, which may include some small deformation caused by tolerances and may include lead angles, arc edges, deformation, and the like.

In the embodiments of the present disclosure, the term “approximately” means a value within a range of allowed process and measurement error that is not strictly defined.

Described above are merely exemplary embodiments of the present disclosure, and are not intended to limit the present disclosure. Any modifications, equivalent replacements, improvements and the like made within the spirit and principles of the present disclosure should be encompassed within the scope of protection of the present disclosure.

1. A display panel, comprising: a display substrate and a cover plate that are opposite to each other, wherein the display substrate comprises:
a substrate; and
a plurality of repeat units on the substrate, wherein at least one of the plurality of repeat units is divided into a display region and a transparent region on at least one side of the display region, and comprises a plurality of sub-pixels in the display region, wherein at least one of the plurality of sub-pixels comprises a pixel circuit and a light-emitting element that are coupled; wherein
the pixel circuit is configured to drive the light-emitting element to emit light, and comprises a storage capacitor, wherein the storage capacitor comprises a first electrode plate and a second electrode plate of which orthographic projections on the substrate are overlapped; and
the light-emitting element comprises a first electrode;
wherein the first electrode is connected to the first electrode plate via a transfer electrode; the first electrode plate, the transfer electrode, the first electrode, and the second electrode plate are disposed in different layers; a material of the first electrode plate and a material of the first electrode both comprise a transparent conductive material; and at least one opening is defined in the display region, wherein the orthographic projection of the first electrode plate on the substrate and an orthographic projection of the first electrode on the substrate are both overlapped with an orthographic projection of the at least one opening on the substrate.

2. The display panel according to claim 1, wherein
a first opening and a second opening that are spaced apart are defined in the display region; and
the first electrode comprises a first sub-electrode and a second sub-electrode that are spaced apart on a same layer, wherein the first sub-electrode is connected to the first electrode plate via the transfer electrode;
wherein an orthographic projection of the first sub-electrode on the substrate is overlapped with an orthographic projection of the first opening on the substrate, the orthographic projection of the first electrode plate on the substrate and an orthographic projection of the second sub-electrode on the substrate are both overlapped with an orthographic projection of the second opening on the substrate, and an orthographic projection of the transfer electrode on the substrate is within an orthographic projection of a space position between the first opening and the second opening on the substrate.

3. The display panel according to claim 2, wherein the orthographic projection of the first sub-electrode on the substrate is not overlapped with the orthographic projections of the first electrode plate and the second electrode plate on the substrate, and the orthographic projection of the second sub-electrode on the substrate is overlapped with the orthographic projections of the first electrode plate and the second electrode plate on the substrate.

4. The display panel according to claim 2, wherein the display substrate further comprises a pixel definition layer on a side, away from the substrate, of the first electrode, wherein the pixel definition layer is configured to define the first opening and the second opening.

5. The display panel according to claim 4, further comprising: a black matrix layer on a side, close to the display substrate, of the cover plate, wherein an orthographic projection of the black matrix layer on the substrate is within an orthographic projection of the pixel definition layer on the substrate.

6. The display panel according to claim 1, wherein
the at least one opening comprises a top-emission opening and a bottom-emission opening that are opposite to each other, wherein the top-emission opening is disposed in a side of the cover plate, and the bottom-emission opening is disposed in a side of the display substrate; and
the display substrate further comprises a reflection electrode on a side, away from the substrate, of the first electrode, wherein an orthographic projection of the reflection electrode on the substrate is overlapped with an orthographic projection of the bottom-emission opening on the substrate, and is not overlapped with an orthographic projection of the top-emission opening on the substrate.

7. The display panel according to claim 6, wherein the reflection electrode is disposed between the first electrode and a pixel definition layer in the display substrate.

8. The display panel according to claim 1, wherein the display substrate further comprises a first transparent conductive layer, an active layer, a gate metal layer, and a second transparent conductive layer that are sequentially laminated in a direction away from the substrate, wherein the first electrode plate and the first transparent conductive layer are disposed on a same layer, the transfer electrode and the gate metal layer are disposed on a same layer, the first electrode and the second transparent conductive layer are disposed on a same layer, and the second electrode plate and the active layer are disposed on a same layer.

9. The display panel according to claim 8, wherein the display substrate further comprises a light-emitting layer and a second electrode that are disposed between the first electrode and the cover plate and are sequentially laminated in the direction away from the substrate, wherein a material of the second electrode comprises a transparent conductive material, and a pixel definition layer in the display substrate is disposed between the light-emitting layer and the first electrode.

10. The display panel according to claim 9, wherein a material of the first transparent conductive layer and a material of the second transparent conductive layer both comprise indium tin oxide, the material of the second electrode comprises indium tin oxide, and a material of the active layer comprises indium gallium zinc oxide.

11. The display panel according to claim 8, wherein the display substrate further comprises: a buffer layer and a gate insulative layer that are disposed between the first transparent conductive layer and the gate metal layer and are sequentially laminated in the direction away from the substrate, and a passivation layer and a planarization layer that are disposed between the gate metal layer and the second transparent conductive layer and are sequentially laminated in the direction away from the substrate, wherein the first electrode is connected to the transfer electrode through a first via running through the passivation layer and the planarization layer, and the transfer electrode is connected to the first electrode plate through a second via running through the gate insulative layer and the buffer layer.

12. The display panel according to claim 11, wherein an orthographic projection of the first via on the substrate is not overlapped with an orthographic projection of the second via on the substrate, and an area of the orthographic projection of the first via on the substrate is greater than an area of the orthographic projection of the second via on the substrate.

13. The display panel according to claim 11, wherein an orthographic projection of the first via on the substrate and an orthographic projection of the second via on the substrate are both within an orthographic projection of a space position between the first opening and the second opening in the display region on the substrate.

14. The display panel according to claim 11, wherein
the display substrate further comprises a metal light shielding layer between the substrate and the buffer layer; and
the pixel circuit is further connected to a plurality of signal lines, and is configured to drive, in response to signals supplied over the plurality of signal lines, the light-emitting element to emit light, wherein the plurality of signal lines comprise a first power line, a second power line, a scan line, a data line, and a sense line, wherein the scan line extends in a first direction and is disposed on a same layer as the gate metal layer, and the first power line, the second power line, the data line, and the sense line extend in a second direction and are disposed on a same layer as the metal light shielding layer, the first direction being intersected with the second direction.

15. The display panel according to claim 14, wherein the gate metal layer is respectively connected to the metal light shielding layer, the first transparent conductive layer, and the active layer through a via running through the gate insulative layer.

16. The display panel according to claim 1, wherein
the display panel further comprises a first color filter layer on a side, close to the display substrate, of the cover plate; and
the display substrate further comprises a second color filter layer on a side, close to the substrate, of the first electrode;
wherein an orthographic projection of the first color filter layer on the substrate and an orthographic projection of the second color filter layer on the substrate are both overlapped with the orthographic projection of the at least one opening on the substrate.

17. The display panel according to claim 16, wherein the second color filter layer is disposed between a passivation layer and a planarization layer in the display substrate.

18. A method for manufacturing a display panel, applicable to manufacturing a display panel comprising a display substrate and a cover plate that are opposite to each other, the method comprising:
providing a substrate;
acquiring the display substrate by forming a plurality of repeat units on a side of the substrate; and
disposing the cover plate on an opposite side of the display substrate;
wherein at least one of the plurality of formed repeat units is divided into a display region and a transparent region on at least one side of the display region, and comprises a plurality of sub-pixels in the display region, wherein at least one of the plurality of sub-pixels comprises a pixel circuit and a light-emitting element that are coupled; wherein the pixel circuit is configured to drive the light-emitting element to emit light, and comprises a storage capacitor, wherein the storage capacitor comprises a first electrode plate and a second electrode plate of which orthographic projections on the substrate are overlapped, and the light-emitting element comprises a first electrode; wherein the first electrode is connected to the first electrode plate via a transfer electrode; the first electrode plate, the transfer electrode, the first electrode, and the second electrode plate are disposed in different layers, and a material of the first electrode plate and a material of the first electrode both comprise a transparent conductive material; and at least one opening is defined in the display region, wherein the orthographic projection of the first electrode plate on the substrate and an orthographic projection of the first electrode on the substrate are both overlapped with an orthographic projection of the at least one opening on the substrate.

19. The method according to claim 18, wherein
the at least one opening comprises a top-emission opening and a bottom-emission opening that are opposite to each other, wherein the top-emission opening is disposed in a side of the cover plate, and the bottom-emission opening is disposed in a side of the display substrate; and
the method further comprises:
forming a reflection electrode on a side, away from the substrate, of the first electrode, wherein an orthographic projection of the formed reflection electrode on the substrate is overlapped with an orthographic projection of the bottom-emission opening on the substrate, and is not overlapped with an orthographic projection of the top-emission opening on the substrate.

20. A display device, comprising: a power supply assembly, and a display panel, wherein
the display panel comprises: a display substrate and a cover plate that are opposite to each other, wherein the display substrate comprises:
a substrate; and
a plurality of repeat units on the substrate, wherein at least one of the plurality of repeat units is divided into a display region and a transparent region on at least one side of the display region, and comprises a plurality of sub-pixels in the display region, wherein at least one of the plurality of sub-pixels comprises a pixel circuit and a light-emitting element that are coupled; wherein
the pixel circuit is configured to drive the light-emitting element to emit light, and comprises a storage capacitor, wherein the storage capacitor comprises a first electrode plate and a second electrode plate of which orthographic projections on the substrate are overlapped; and
the light-emitting element comprises a first electrode;
wherein the first electrode is connected to the first electrode plate via a transfer electrode; the first electrode plate, the transfer electrode, the first electrode, and the second electrode plate are disposed in different layers; a material of the first electrode plate and a material of the first electrode both comprise a transparent conductive material; and at least one opening is defined in the display region, wherein the orthographic projection of the first electrode plate on the substrate and an orthographic projection of the first electrode on the substrate are both overlapped with an orthographic projection of the at least one opening on the substrate;
the power supply assembly is connected to the display panel, and is configured to supply power to the display panel.
